(19) United States
(12) Patent Application Publication
(10) Pub. No.: US 2025/0084270 A1
(43) Pub. Date: Mar. 13, 2025

(54) CURABLE COMPOSITION, FILM FORMING METHOD AND MANUFACTURING METHOD

(71) Applicant: CANON KABUSHIKI KAISHA, Tokyo (JP)

(72) Inventors: MASANOBU OOTSUKA, Tokyo (JP); TOSHIKI ITO, Kanagawa (JP); JUNJI ITO, Kanagawa (JP); AYANO MASHIDA, Kanagawa (JP)

(21) Appl. No.: 18/823,843

(22) Filed: Sep. 4, 2024

(30) Foreign Application Priority Data
Sep. 8, 2023 (JP) 2023-146501

(51) Int. Cl. C09D 11/38; C08F 20/24; C08F 30/08; C08F 283/12; C09D 11/033; C09D 11/101; C09D 11/107; C09D 11/36; G03F 7/00; H01L 21/027

(52) U.S. Cl. CPC C09D 11/38; C08F 20/24; C08F 30/08; C08F 283/124; C09D 11/033; C09D 11/101; C09D 11/107; C09D 11/36; G03F 7/0002; H01L 21/0271

(57) ABSTRACT

A curable composition containing a polymerizable compound, a photopolymerization initiator, and a solvent, wherein the curable composition has a viscosity of not less than 1.3 mPa·s and not more than 60 mPa·s at 23° C. and at 1 atm, a content of the solvent with respect to whole of the curable composition is not less than 5 vol % and not more than 95 vol %, a boiling point of the solvent is not less than 135° C. at 1 atm, and defining a surface tension of a composition obtained by removing the solvent from the curable composition at 1 atm as yl [mN/m] and the surface tension of the solvent at 23° C. and at 1 atm as γ2 [mN/m], γ1 is not more than 30, γ2 is not more than 24, and γ1 is larger than γ2.

### BACKGROUND OF THE INVENTION

### Field of the Invention

The present invention relates to a curable composition, a film forming method and manufacturing method.

### Description of the Related Art

For semiconductor devices and MEMS, requirements of micronization are increasing, and as a micropatterning technique, an imprint technique (optical imprint technique) has received a great deal of attention as a microfabrication technique. In the imprint technique, a curable composition is cured in a state in which a mold with a fine concave-convex pattern formed on the surface is in contact with the curable composition supplied (applied) onto a substrate. Thus, the pattern of the mold is transferred to the cured film of the curable composition, thereby forming the pattern on the substrate. According to the imprint technique, it is possible to form, on a substrate, a fine pattern (structure) on a several nanometer order.

A master mold used in the imprint technique is very expensive because a fine pattern is formed on the surface of silicon, silica glass, a metal, or the like by precision machining. Hence, a replica mold having, on the surface of a mold base material (for example, silica glass), a cured product layer to which the fine pattern of the master mold is transferred is manufactured by the imprint technique. As a curable composition used to form the cured product layer of the replica mold, a composition containing fluorine atoms is proposed in Japanese Patent No. 5794387.

A method of forming a replica mold using the imprint technique will be described. First, a curable composition (curable composition for replica) in liquid form is discretely dropped (arranged) in a pattern formation region on a mold base material (substrate). The droplets of the curable composition arranged in the pattern formation region spread on the mold base material. This phenomenon is called pre-spreading. Next, a master mold (mold) is brought into contact with (pressed against) the curable composition on the mold base material. Thus, the droplets of the curable composition spread to the whole region of the gap between the mold base material and the master mold by a capillary phenomenon. This phenomenon is called spreading. Also, by the capillary phenomenon, the curable composition fills concave portions that form the pattern of the master mold. This phenomenon is called filling. Note that the time until spreading and filling are completed is called a filling time. If the filling of the curable composition is completed, the curable composition is irradiated with light to cure the curable composition. Then, the master mold is released from the cured curable composition on the mold base material. By executing these steps, the pattern of the master mold is transferred to the curable composition on the mold base material, and the pattern of the curable composition (cured product layer) is formed.

In the conventional technique, however, if the mold is brought into contact with the curable composition in a state in which the droplets of the curable composition arranged on the substrate are not in contact with each other, bubbles entrapped between the droplets of the curable composition become large in a space between the mold and the substrate. Hence, a long time is needed until the bubbles are diffused to the mold or the substrate and disappear, and this is one of factors for lowering productivity (throughput).

### SUMMARY OF THE INVENTION

The present invention provides a new technique concerning a curable composition.

According to one aspect of the present invention, there is provided a curable composition containing a polymerizable compound (a), a photopolymerization initiator (b), and a solvent (c), wherein the curable composition has a viscosity of not less than 1.3 mPa·s and not more than 60 mPa·s at 23° C. and at 1 atm, a content of the solvent (c) with respect to whole of the curable composition is not less than 5 vol % and not more than 95 vol %, a boiling point of the solvent (c) is not less than 135° C. at 1 atm, and defining a surface tension of a composition obtained by removing the solvent (c) from the curable composition at 1 atm as γ1 [mN/m] and the surface tension of the solvent (c) at 23° C. and at 1 atm as γ2 [mN/m], γ1 is not more than 30, γ2 is not more than 24, and γ1 is larger than γ2.

Further aspects of the present invention will become apparent from the following description of exemplary embodiments with reference to the attached drawings.

### BRIEF DESCRIPTION OF THE DRAWINGS

FIGS. 1A to 1G are views for explaining a film forming method according to an aspect of the present invention.

FIGS. 2A to 2D are views for explaining the flow behavior of the droplets of a curable composition during a waiting step.

FIGS. 3A to 3G are views for explaining a film forming method according to an aspect of the present invention.

FIG. 4 is a view showing comparison between a contact step in the conventional technique and a contact step according to the present invention.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

To provide a new technique concerning a curable composition, the present inventors found a curable composition and process conditions, which can form a practically continuous liquid film before the droplets of a curable composition discretely arranged on a substrate combine with each other and a mold comes into contact with the curable composition.

### [Curable Composition]

A curable composition (A) according to the present invention is a curable composition for inkjet. The curable composition (A) according to the present invention is a composition containing at least a component (a) as a polymerizable compound, a component (b) as a photopolymerization initiator, and a component (c) as a solvent. The curable composition (A) according to the present invention may further contain at least one of a component (as) that is a silicon compound having polymerizability, a component (af) that is a fluorine compound having polymerizability, and a component (d) that is a nonpolymerizable compound.

In this specification, a cured film means a film cured by polymerizing the curable composition on a substrate. Note that the shape of the cured film is not particularly limited, and the cured film may have a pattern shape on the surface, or may not.

### <Component (as): Silicon-containing Polymerizable Compound>

A silicon compound as the component (as) may be understood as a silicon-containing polymerizable compound. In this specification, the silicon-containing polymerizable compound is a compound that reacts with a polymerizing factor (for example, a radical) generated from a photopolymerization initiator (the component (b)), and forms a film made of a polymer compound by a chain reaction (polymerization reaction).

An example of the silicon-containing polymerizable compound is a radical polymerizable compound. The polymerizable compound as the component (as can be formed by only one type of a polymerizable compound, and can also be formed by a plurality of types of polymerizable compounds.

Examples of the silicon-containing radical polymerizable compound are a (meth)acrylate-based compound, a (meth)acrylamide-based compound, a vinylbenzene-based compound, an aryl ether-based compound, a vinyl ether-based compound, and a maleimide-based compound.

The silicon-containing polymerizable compound can be linear or branched. As the silicon-containing polymerizable compound, for example, the following structures can be used. An example of a polymerizable functional group in a group Q having a polymerizable functional group is a radical polymerizable functional group. Detailed examples of the radical polymerizable functional group are a (meth)acrylate-based compound, a (meth)acrylamide-based compound, a vinylbenzene-based compound, an aryl ether-based compound, a vinyl ether-based compound, and a maleimide-based compound. The group Q having a polymerizable functional group can be a group having the above-described polymerizable functional group.

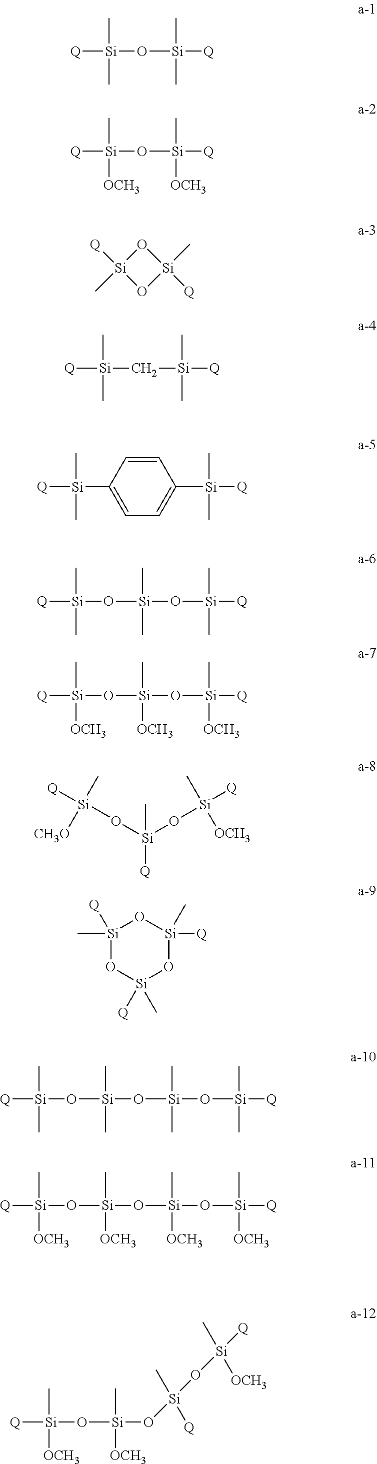

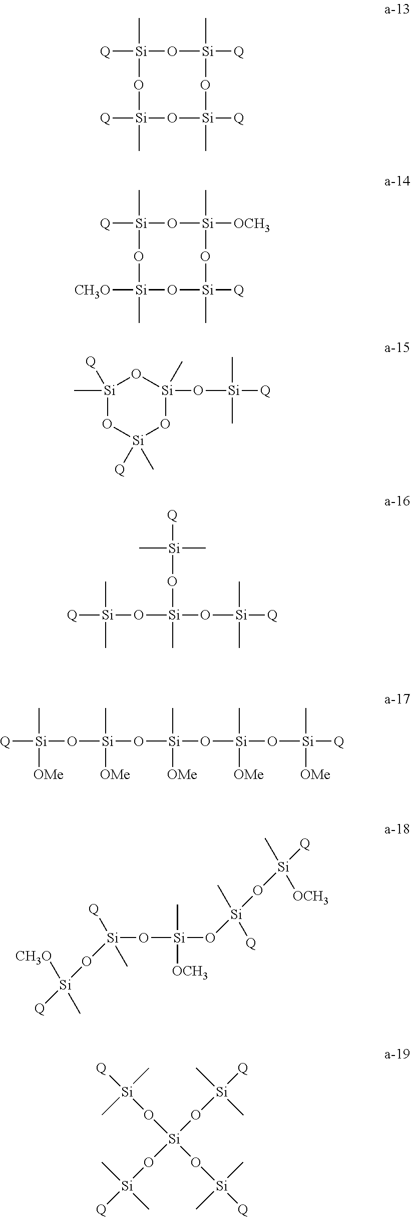

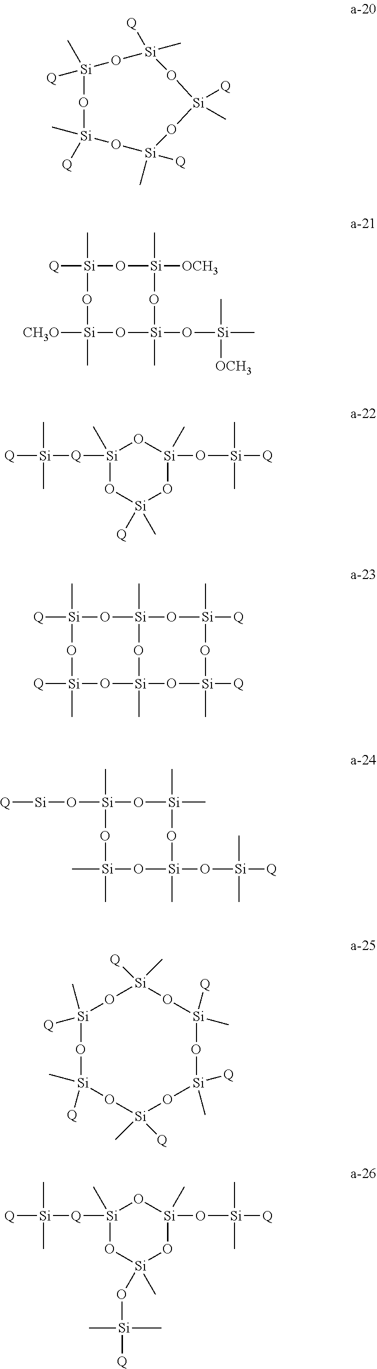

In addition, examples of the silicon-containing polymerizable compound are a silsesquioxane skeleton indicated by formula (1) below and a silicone skeleton indicated by formula (2) below. Here, in formula (1), m+n=8 (8≥m>1), and R₁ is a bivalent organic group. Also, in formula (2), A, B, R₂, and R₃ are an alkyl group, a cycloalkyl group, an alkoxy group, a phenyl group, or a hydroxyl group having a carbon number of 1 to 6 independently (t is an integer of 1 to 3), and at least one of A and B is a polymerizable functional group.

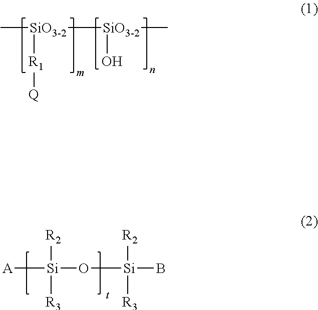

An example of a polymerizable functional group in groups Q, A, and B having a polymerizable functional group is a radical polymerizable functional group. Detailed examples of the radical polymerizable functional group are a (meth)acrylate-based compound, a (meth)acrylamide-based compound, a vinylbenzene-based compound, an aryl ether-based compound, a vinyl ether-based compound, and a maleimide-based compound. The group Q having a polymerizable functional group can be a group having the above-described polymerizable functional group.

A silicon-containing (meth)acrylate-based compound includes a compound having one or more acryloyl groups or methacryloyl groups.

Examples of a silicon-containing monofunctional (meth)acrylate-based compound having one acryloyl group or methacryloyl group are as follows, but the compound is not limited to these examples.
(2-acryloylethoxy)trimethylsilane,
N-(3-acryloyl-2-hydroxypropyl)-3-aminopropyltriethoxysilane,
acryloxymethyltrimethoxysilane,
(acryloxymethyl)phenethyltrimethoxysilane,
acryloxymethyltrimethylsilane,
(3-acryloxypropyl)dimethylmethoxysilane,
(3-acryloxypropyl)methylbis(trimethylsiloxy)silane,
(3-acryloxypropyl)methyldichlorosilane,
(3-acryloxypropyl)methyldiethoxysilane,
(3-acryloxypropyl)methyldimethoxysilane,
(3-acryloxypropyl)trichlorosilane,
(3-acryloxypropyl)trimethoxysilane,
(3-acryloxypropyl)tris(trimethylsiloxy)silane,
acryloxytriisopropylsilane,
acryloxytrimethylsilane,
methacryloxymethyltrimethoxysilane,
O-(methacryloxyethoxy)carbamoylpropylmethyldimethoxysilane,
(methacryloxymethyl)bis(trimethylsiloxy)methylsilane,
N-(3-methacryloyl-2-hydroxypropyl)-3-aminopropyltriethoxysilane,
(methacryloxymethyl)methyldimethoxysilane,
(methacryloxymethyl)methyldiethoxysilane,
methacryloxymethylmethyltriethoxysilane,
methacryloxypropyltrimethoxysilane,
methacryloylpropyltriisopropoxysilane,
O-(methacryloxyethyl)-N-(triethoxysilylpropyl) carbamate,
methacryloxypropylmethyldimethoxysilane,
methacryloxypropylmethyldiethoxysilane,
methacryloxypropyldimethylmethoxysilane,
methacryloxypropyldimethylethoxysilane,
(methacryloxymethyl)dimethylethoxysilane,
methacryloxypropyltriethoxysilane,
methacryloxypropylsilatrane,
methacryloxypentamethyldisiloxane,
(methacryloxymethyl)phenyldimethylsilane,
methacryloxytrimethylsilane,
methacryloxymethyltrimethylsilane,
(3-methacryloxy-2-hydroxypropoxypropyl)methyl bis(trimethylsiloxy)silane,
methacryloxypropylpentamethyldisiloxane,
O-(methacryloxyethyl)-3-[bis(trimethylsiloxy)methylsilyl]propylcarbamate,
methacryloxymethyltris(trimethylsiloxy)silane,
methacryloxyethoxytrimethylsilane,
(3-methacryloxy-2-hydroxypropoxypropyl)methyl bis(trimethylsiloxy)silane,
methacryloxypropyltris(vinyldimethylsiloxy)silane,
methacryloxypropyltris(trimethylsiloxy)silane,
3-methacryloxypropyltriacetoxysilane,
methacryloxypropylmethyldichlorosilane,
methacryloxypropyltrichlorosilane,
3-methacryloxypropylbis(trimethylsiloxy)methylsilane,
3-methacroloxypropyldimethylchlorosilane,
O-methacryloxy(polyethyleneoxy)trimethylsilane,
poly(methacryloxypropylsilsesquioxane),
methacryloxypropylheptaisobutyl-T8-silsesquioxane, and
methacryloxypropyltris(trimethylsiloxy)silane

Examples of the commercially available products of the above-described silicon-containing monofunctional (meth)acrylic compounds are as follows, but the products are not limited to these examples.

SIA0160.0, SIA0180.0, SIA0182.0, SIA0184.0, SIA0186.0, SIA0190.0, SIA0194.0, SIA0196.0, SIA0197.0, SIA0198.0, SIA0199.0, SIA0200.0, SIA0200.A1, SIA0210.0, SIA0315.0, SIA0320.0, SIM6483.0, SIM6487.5, SIM6480.76, SIM6481.2, SIM6486.1, SIM6481.1, SIM6481.46, SIM6481.43, SIM6482.0, SIM6487.4, SIM6487.35, SIM6480.8, SIM6486.9, SIM6486.8, SIM6486.5, SIM6486.4, SIM6481.3, SIM6487.3, SIM6487.1, SIM6487.6, SIM6486.14, SIM6481.48, SIM6481.5, SIM6491.0, SIM6485.6, SIM6481.15, SIM6487.0, SIM6481.05, SIM6485.8, SIM6481.0, SIM6487.4LI, SIM6481.16, SIM6487.8, SIM6487.6HP, SIM6487.17, SIM6486.7, SIM6487.2, SIM6486.0, SIM6486.2, SIM6487.6-06, SIM6487.6-20, SIM6485.9, SST-R8C42, SLT-3R01, and SIM6486.65 (manufactured by GELEST), and TM-0701T, FM-0711, FM-0721, and FM-0725 (manufactured by JNC)

A silicon-containing (meth)acrylamide-based compound includes a compound having one or more acrylamide groups or methacrylamide groups. Examples of a silicon-containing monofunctional (meth)acrylamide-based compound having one acrylamide group or methacrylamide group are as follows, but the compound is not limited to these examples. 3-acrylamidopropyltrimethoxysilane, and 3-acrylamidopropyltris(trimethylsiloxy)silane

Examples of the commercially available products of the above-described silicon-containing monofunctional (meth)acrylamide compounds are as follows, but the products are not limited to these examples. SIA0146.0, and SIA0150.0 (manufactured by GELEST)

Examples of a polyfunctional (meth)acrylate-based compound having two or more acryloyl groups or methacryloyl groups are as follows, but the compound is not limited to these examples.
linear polydimethylsiloxane modified on both ends with acryloxypropyl groups,
linear polydimethylsiloxane modified on both ends with methacryloxypropyl groups,
cyclic siloxane modified with multiple acryloxypropyl groups,
cyclic siloxane modified with multiple methacryloxypropyl groups,
silsesquioxane modified with multiple acryloxypropyl groups, and
silsesquioxane modified with multiple methacryloxypropyl groups

Examples of the commercially available products of the above-described silicon-containing monofunctional (meth)acrylate compounds are as follows, but the products are not limited to these examples.

SIA0200.2, SIA0200.3, SIM6487.42, DMS-R11, DMS-R05, DMS-R22, DMS-R18, DMS-R31 (manufactured by GELEST), FM-7711, FM-7721, FM-7725 (manufactured by JNC), X-22-2445 (manufactured by Shin-Etsu Chemical), and AC-SQ TA-100, MAC-SQ TM-100, AC-SQ SI-20, MAC-SQ SI-20 (manufactured by TOAGOSEI)

In addition, for example, the following compounds can be synthetized and/or obtained from known literature 1.
linear modified polydimethylsiloxane with methacryloxypropyl groups on both ends (MA-Si-12),
8-membered ring siloxane modified with four methacryloxypropyl groups (8-ring), and
10-membered ring siloxane modified with five methacryloxypropyl groups (10-ring)
Literature 1: Ogawa et al. “Ultraviolet curable branched siloxanes as low-k dielectric for imprint lithography”

### <Component (a): Silicon-Free Polymerizable Compound>

The component (a) contains a silicon-free polymerizable compound. In this specification, the silicon-free polymerizable compound is a compound that reacts with a polymerizing factor (for example, a radical) generated from a photopolymerization initiator (the component (b)), and forms a film made of a polymer compound by a chain reaction (polymerization reaction).

An example of the polymerizable compound as described above is a radical polymerizable compound. The polymerizable compound as the component (a) can be formed by only one type of a polymerizable compound, and can also be formed by a plurality of types (one or more types) of polymerizable compounds.

Examples of the radical polymerizable compound are a silicon-free (meth)acrylic compound, a silicon-free styrene-based compound, a silicon-free vinyl-based compound, an silicon-free allylic compound, a silicon-free fumaric compound, and a silicon-free maleic compound.

### <Component (af): Fluorine-Containing Polymerizable Compound>

A fluorine compound as the component (af) may be understood as a fluorine-containing polymerizable compound. In this specification, the fluorine-containing polymerizable compound is a compound that reacts with a polymerizing factor (for example, a radical) generated from a photopolymerization initiator (the component (b)), and forms a film made of a polymer compound by a chain reaction (polymerization reaction).

An example of the fluorine-containing polymerizable compound is a radical polymerizable compound. The polymerizable compound as the component (af) can be formed by only one type of a polymerizable compound, and can also be formed by a plurality of types (one or more types) of polymerizable compounds.

Examples of the fluorine-containing radical polymerizable compound are a (meth)acrylate-based compound, a (meth)acrylamide-based compound, a vinylbenzene-based compound, an aryl ether-based compound, a vinyl ether-based compound, and a maleimide-based compound.

Examples of the commercially available products of the above-described fluorine-containing monofunctional (meth)acrylate-based compounds are as follows, but the products are not limited to these examples. 2,2,2-trifluoroethyl acrylate, 2,2,3,4,4,4-hexafluorobutyl methacrylate, 1,1,1,3,3,3,3-hexafluoroisopropyl acrylate, 2,2,3,3,3,3,3-hexafluoroisopropyl methacrylate 2,4,4,4-heptafluorobutyl methacrylate, 2,2,2-trifluoroethyl methacrylate, 1,1,1,3,3,3,3-hexafluoroisopropyl methacrylate, 1H,1H,2H,2H-nonafluorohexyl methacrylate, 1H,1H,2H,2H-nonafluorohexyl acrylate, 1H,1H,2H,2H-nonafluorohexyl methacrylate, 1H,1H,5H-octafluoropentyl acrylate, pentafluorophenyl acrylate, 2,2,3,3,3-pentafluoropropyl methacrylate, pentafluorobenzyl methacrylate, 2,2,3,3-tetrafluoropropyl acrylate, 1H,1H,2H,2H-tridecafluoro-n-octyl methacrylate, 1H,1H,2H,2H-tridecafluoro-n-octyl acrylate, 2,2,3,3-tetrafluoropropyl methacrylate, 1H,1H,2H,2H-heptadecafluorodecyl acrylate, 2,2,3,3,4,4,5,5,6,6,7-dodecafluoroheptyl acrylate, 2,2,3,3,4,4,5,5,5,6,6,7,7-dodecafluoroheptyl methacrylate, 1H,1H,5H-octafluoropentyl acrylate, meth Pentafluorophenyl acrylate (manufactured by Tokyo Chemical Industry)
C6(meth)acrylate, C4(meth)acrylate, C2(meth)acrylate (manufactured by Uni-chem)
Viscoat 3F, Viscoat 4F, Viscoat 8F, Viscoat 8FM, Viscoat 13F (manufactured by OSAKA ORGANIC CHEMICAL INDUSTRY)
1H,1H,2H,2H-heptadecafluorodecyl methacrylate, 1,1,1,3,3,3-hexafluoroisopropyl methacrylate, 1H,1H,5H-octafluoropentyl methacrylate, pentafluorophenyl acrylate, 2,2,2-trifluoroethyl acrylate, 2,2,2-trifluoroethyl methacrylate (manufactured by Polysciences)
methyl-2-fluoroacrylate, 2,2,2-trifluoroethyl acrylate, 2,2,3,3,3-pentafluoropropyl acrylate, 2-(perfluorobutyl)ethyl acrylate, 3-perfluorohexyl-2-hydroxypropyl acrylate, 1H,1H,3H-tetrafluoropropyl acrylate, 1H,1H,5H-octafluoropentyl acrylate, 1H,1H,7H-dodecafluoroheptyl acrylate, 1H-1-(trifluoromethyl)trifluoroethyl acrylate, 1H,1H,3H-hexafluorobutyl acrylate, 2,2,2-trifluoroethyl methacrylate, 2,2,3,3,3-pentafluoropropyl methacrylate, 2-(perfluorobutyl)ethyl methacrylate, 1H,1H,3H-tetrafluoropropyl methacrylate, 1H,1H,5H-octafluoropentyl methacrylate, 1H,1H,7H-dodecafluoroheptyl methacrylate, 1H-1-(trifluoromethyl)trifluoroethyl methacrylate, 1H,1H,3H-hexafluorobutyl methacrylate (manufactured by DAIKIN)

Examples of the above-described fluorine-containing polyfunctional (meth)acrylate-based compound obtained using a method disclosed in Japanese Patent No. 3963028 are as follows, but the compound is not limited to these examples,

a compound obtained by introducing a linking group to the polyalcohol part of trivalent trimethylolethane, quadrivalent pentaerythritol, or hexavalent dipentaerythritol using a normal organic synthetic reaction, forming a core part containing fluorine in high content by a whole fluorination reaction, and then introducing an acrylic group to an end.

The silicon-free (meth)acrylic compound includes a compound having one or more acryloyl groups or methacryloyl groups. Examples of a silicon-free monofunctional (meth)acrylic compound having one acryloyl group or methacryloyl group are as follows, but the compound is not limited to these examples.

Phenoxyethyl(meth)acrylate, phenoxy-2-methylethyl(meth)acrylate, phenoxyethoxyethyl(meth)acrylate, 3-phenoxy-2-hydroxypropyl(meth)acrylate, 2-phenylphenoxyethyl(meth)acrylate, 4-phenylphenoxyethyl(meth)acrylate, 3-(2-phenylphenyl)-2-hydroxypropyl(meth)acrylate, (meth)acrylate of EO-modified p-cumylphenol, 2-bromophenoxyethyl(meth)acrylate, 2,4-dibromophenoxyethyl(meth)acrylate, 2,4,6-tribromophenoxyethyl(meth)acrylate, EO-modified phenoxy (meth)acrylate, PO-modified phenoxy (meth)acrylate, polyoxyethylenenonylphenylether (meth)acrylate, isobornyl(meth)acrylate, 1-adamantyl(meth)acrylate, 2-methyl-2-adamantyl(meth)acrylate, 2-ethyl-2-adamantyl(meth)acrylate, bornyl(meth)acrylate, tricyclodecanyl(meth)acrylate, dicyclopentanyl(meth)acrylate, dicyclopentenyl(meth)acrylate, cyclohexyl(meth)acrylate, 4-butylcyclohexyl(meth)acrylate, acryloylmorpholine, 2-hydroxyethyl(meth)acrylate, 2-hydroxypropyl(meth)acrylate, 2-hydroxybutyl(meth)acrylate, methyl(meth)acrylate, ethyl(meth)acrylate, propyl(meth)acrylate, isopropyl(meth)acrylate, butyl(meth)acrylate, amyl(meth)acrylate, isobutyl(meth)acrylate, t-butyl(meth)acrylate, pentyl(meth)acrylate, isoamyl(meth)acrylate, hexyl(meth)acrylate, heptyl(meth)acrylate, octyl(meth)acrylate, isooctyl(meth)acrylate, 2-ethylhexyl(meth)acrylate, nonyl(meth)acrylate, decyl(meth)acrylate, isodecyl(meth)acrylate, undecyl(meth)acrylate, dodecyl(meth)acrylate, lauryl(meth)acrylate, stearyl(meth)acrylate, isostearyl(meth)acrylate, benzyl(meth)acrylate, tetrahydrofurfuryl(meth)acrylate, butoxyethyl(meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl(meth)acrylate, methoxypolyethyleneglycol (meth)acrylate, methoxypolypropyleneglycol (meth)acrylate, diacetone (meth)acrylamide, isobutoxymethyl (meth)acrylamide, N,N-dimethyl (meth)acrylamide, t-octyl (meth)acrylamide, dimethylaminoethyl(meth)acrylate, diethylaminoethyl(meth)acrylate, 7-amino-3,7-dimethyloctyl(meth)acrylate, N,N-diethyl(meth)acrylamide, N,N-dimethylaminopropyl (meth)acrylamide, 1- or 2-naphthyl(meth)acrylate, 1- or 2-naphthylmethyl(meth)acrylate, 3- or 4-phenoxybenzyl(meth)acrylate, and cyanobenzyl (meth)acrylate.

Examples of the commercially available products of the above-described silicon-free monofunctional (meth)acrylic compounds are as follows, but the products are not limited to these examples.

ARONIX® M101, M102, M110, M111, M113, M117, M5700, TO-1317, M120, M150, and M156 (manufactured by TOAGOSEI) MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY)
Light Acrylate BO-A, EC-A, DMP-A, THF-A, HOP-A, HOA-MPE, HOA-MPL, PO-A, P-200A, NP-4EA, NP-8EA, Epoxy Ester M-600A, POB-A, and OPP-EA (manufactured by KYOEISHA CHEMICAL)
KAYARAD® TC110S, R-564, and R-128H (manufactured by NIPPON KAYAKU)
NK Ester AMP-10G, AMP-20G, and A-LEN-10 (manufactured by SHIN-NAKAMURA CHEMICAL)
FA-511A, 512A, and 513A (manufactured by Hitachi Chemical) PHE, CEA, PHE-2, PHE-4, BR-31, BR-31M, and BR-32 (manufactured by DKS) VP (manufactured by BASF)
and ACMO, DMAA, and DMAPAA (manufactured by Kohjin).

Examples of a silicon-free polyfunctional (meth)acrylic compound having two or more acryloyl groups or methacryloyl groups are as follows, but the compound is not limited to these examples.

Trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydoxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, EO- and PO-modified 2,2-bis(4-((meth)acryloxy)phenyl)propane, o-, m-, or p-benzene di(meth)acrylate, and o-, m-, or p-xylylene di(meth)acrylate.

Examples of the commercially available products of the above-described silicon-free polyfunctional (meth)acrylic compounds are as follows, but the products are not limited to these examples.

Yupimer® UV SA1002 and SA2007 (manufactured by Mitsubishi Chemical) Viscoat #195, #230, #215, #260, #335HP, #295, #300, #360, #700, GPT, and 3PA (manufactured by OSAKA ORGANIC CHEMICAL INDUSTRY)
Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL)
KAYARAD® PET-30, TMPTA, R-604, DPHA, DPCA-20, -30, -60, and -120, HX-620, D-310, and D-330 (manufactured by NIPPON KAYAKU)
ARONIX® M208, M210, M215, M220, M240, M305, M309, M310, M315, M325, and M400 (manufactured by TOAGOSEI)
Ripoxy® VR-77, VR-60, and VR-90 (manufactured by Showa Highpolymer) OGSOL EA-0200 and OGSOL EA-0300 (manufactured by Osaka Gas Chemicals).

Note that in the above-described compound county, (meth)acrylate means acrylate or methacrylate having an alcohol residue equal to acrylate. A (meth)acryloyl group means an acryloyl group or a methacryloyl group having an alcohol residue equal to the acryloyl group. EO indicates ethylene oxide, and an EO-modified compound A indicates a compound in which a (meth)acrylic acid residue and an alcohol residue of a compound A bond via the block structure of an ethylene oxide group. Also, PO indicates a propylene oxide, and a PO-modified compound B indicates a compound in which a (meth)acrylic acid residue and an alcohol residue of a compound B bond via the block structure of a propylene oxide group.

Practical examples of the silicon-free styrene-based compound are as follows, but the compound is not limited to these examples.

Alkylstyrene such as styrene, 2,4-dimethyl-α-methylstyrene, o-methylstyrene, m-methylstyrene, p-methylstyrene, 2,4-dimethylstyrene, 2,5-dimethylstyrene, 2,6-dimethylstyrene, 3,4-dimethylstyrene, 3,5-dimethylstyrene, 2,4,6-trimethylstyrene, 2,4,5-trimethylstyrene, pentamethylstyrene, o-ethylstyrene, methylstyrene, p-ethylstyrene, diethylstyrene, triethylstyrene, propylstyrene 2,4-diisopropylstyrene, butylstyrene, hexylstyrene, heptylstyrene, and octylstyrene; styrene halide such as fluorostyrene, o-chlorostyrene, m-chlorostyrene, p-chlorostyrene, o-bromostyrene, m-bromostyrene, p-bromostyrene, dibromostyrene, and iodostyrene; and a compound having a styryl group as a polymerizable functional group, such as nitrostyrene, acetylstyrene, o-methoxystyrene, m-methoxystyrene, p-methoxystyrene, o-hydroxystyrene, m-hydroxystyrene, p-hydroxystyrene, 2-vinylbiphenyl, 3-vinylbiphenyl, 4-vinylbiphenyl, 1-vinylnaphthalene, 2-vinylnaphthalene, 4-vinyl-p-terphenyl, 1-vinylanthracene, α-methylstyrene, o-isopropenyltoluene, m-isopropenyltoluene, p-isopropenyltoluene, 2,3-dimethyl-α-methylstyrene, 3,5-dimethyl-α-methylstyrene, p-isopropyl-α-methylstyrene, α-ethylstyrene, α-chlorostyrene, divinylbenzene, diisopropylbenzene, and divinylbiphenyl.

Practical examples of the silicon-free vinyl-based compound are as follows, but the compound is not limited to these examples.

Vinylpyridine, vinylpyrrolidone, vinylcarbazole, vinyl acetate, and acrylonitrile; conjugated diene monomers such as butadiene, isoprene, and chloroprene; vinyl halide such as vinyl chloride and vinyl bromide; a compound having a vinyl group as a polymerizable functional group, for example, vinylidene halide such as vinylidene chloride, vinyl ester of organic carboxylic acid and its derivative (for example, vinyl acetate, vinyl propionate, vinyl butyrate, vinyl benzoate, and divinyl adipate), and (meth)acrylonitrile.

Note that in this specification, (meth)acrylonitrile is a general term for acrylonitrile and methacrylonitrile.

Examples of the silicon-free allylic compound are as follows, but the compound is not limited to these examples.

Allyl acetate, allyl benzoate, diallyl adipate, diallyl terephthalate, diallyl isophthalate, and diallyl phthalate.

Examples of the silicon-free fumaric compound are as follows, but the compound is not limited to these examples.

Dimethyl fumarate, diethyl fumarate, diisopropyl fumarate, di-sec-butyl fumarate, diisobutyl fumarate, di-n-butyl fumarate, di-2-ethylhexyl fumarate, and dibenzyl fumarate.

Examples of the silicon-free maleic compound are as follows, but the compound is not limited to these examples.

Dimethyl maleate, diethyl maleate, diisopropyl maleate, di-sec-butyl maleate, diisobutyl maleate, di-n-butyl maleate, di-2-ethylhexyl maleate, and dibenzyl maleate.

Other examples of the silicon-free radical polymerizable compound are as follows, but the compound is not limited to these examples.

Dialkylester of itaconic acid and its derivative (for example, dimethyl itaconate, diethyl itaconate, diisopropyl itaconate, di-sec-butyl itaconate, diisobutyl itaconate, di-n-butyl itaconate, di-2-ethylhexyl itaconate, and dibenzyl itaconate), an N-vinylamide derivative of organic carboxylic acid (for example, N-methyl-N-vinylacetamide), and maleimide and its derivative (for example, N-phenylmaleimide and N-cyclohexylmaleimide).

If the component (a) is formed by a plurality of types of compounds having one or more polymerizable functional groups, a monofunctional compound and a polyfunctional compound are preferably included. This is because if a monofunctional compound and a polyfunctional compound are combined, a cured film having well-balanced performance, for example, a high mechanical strength, a high dry etching resistance, and a high heat resistance can be obtained.

The film forming method of the present invention requires a few milliseconds to a few hundreds of seconds until droplets of the curable composition (A) discretely arranged on a substrate combine with each other and form a practically continuous liquid film, so a waiting step (to be described later) is necessary. In this waiting step, the solvent (c) is volatilized, but the polymerizable compound (a) is not volatilized. Hence, in the polymerizable compound (a) that can contain a plurality of types of compounds, the boiling points of all the compounds at normal pressure are preferably 250° C. or more, more preferably 300° C. or more, and further preferably 350° C. or more. Also, to obtain a high dry etching resistance and a high heat resistance, the cured film of the curable composition (A) preferably contains at least a compound having a cyclic structure such as an aromatic structure, an aromatic heterocyclic structure, or an alicyclic structure. Note that the normal pressure is assumed to be 1 atm (atmospheric pressure).

The boiling point of the polymerizable compound (a) is almost correlated with the molecular weight. Therefore, the molecular weights of all the polymerizable compounds (a) are preferably 200 or more, more preferably 240 or more, and further preferably 250 or more. However, even when the molecular weight is 200 or less, the compound is preferably usable as the polymerizable compound (a) of the present invention if the boiling point is 250° C. or more.

In addition, the vapor pressure at 80° C. of the polymerizable compound (component (a)) is preferably 0.001 mmHg or less. This is so because, although it is favorable to heat the curable composition when accelerating volatilization of the solvent (component (c)) (to be described later), it is necessary to suppress volatilization of the polymerizable compound (component (a)) during heating.

Note that the boiling point and the vapor pressure of each organic compound at normal pressure can be calculated by, for example, Hansen Solubility Parameters in Practice (HSPiP) 5th Edition. 5.3.04.

Practical examples of the polymerizable compound (component (a)) having a boiling point of 250° C. or more are as follows, but the compound is not limited to these examples.
dicyclopentanyl acrylate (boiling point=262° C., molecular weight=206)
dicyclopentenyl acrylate (boiling point=270° C., molecular weight=204)
1,3-cyclohexanedimethanol diacrylate (boiling point=310° C., molecular weight=252) m-xylylene diacrylate (boiling point=336° C., molecular weight=246)
1,4-cyclohexanedimethanol diacrylate (boiling point=339° C., molecular weight=252)
4-hexylresolsinol diacrylate (boiling point=379° C., molecular weight=302) 6-phenylhexane-1,2-diol diacrylate (boiling point=381° C., molecular weight=302)
7-phenylheptan-1,2-diol diacrylate (boiling point=393° C., molecular weight=316)
1,3-bis((2-hydroxyethoxy)methyl)cyclohexane diacrylate (boiling point=403° C., molecular weight=340) 8-phenyloctane-1,2-diol diacrylate (boiling point=404° C., molecular weight=330)
1,3-bis((2-hydroxyethoxy)methyl)benzene diacrylate (boiling point=408° C., molecular weight=334)
1,4-bis((2-hydroxyethoxy)methyl)cyclohexane diacrylate (boiling point=445° C., molecular weight=340)
3-phenoxybenzyl acrylate (mPhOBzA, OP=2.54, boiling point=367.4° C., 80° C. vapor pressure=0.0004 mmHg, molecular weight=254.3)

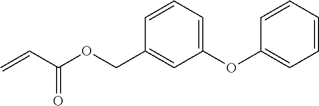 [SMILES: C=CC(=O)OCc1cccc(Oc2ccccc2)c1]

1-naphthyl acrylate (NaA, OP=2.27, boiling point=317° C., 80° C. vapor pressure=0.0422 mmHg, molecular weight=198)

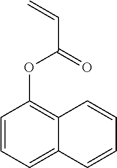

2-phenylphenoxyethyl acrylate (PhPhOEA, OP=2.57, boiling point=364.2° C., 80° C. vapor pressure=0.0006 mmHg, molecular weight=268.3)

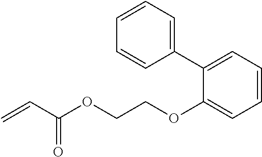 [SMILES: C=CC(=O)OCCOc1ccccc1-c1ccccc1]

1-naphthylmethyl acrylate (Na1MA, OP=2.33, boiling point=342.1° C., 80° C. vapor pressure=0.042 mmHg, molecular weight=212.2) 0.1

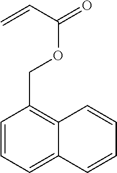 [SMILES: C=CC(=O)OCc1cccc2ccccc12]

2-naphthylmethyl acrylate (Na2MA, OP=2.33, boiling point=342.1° C., 80° C. vapor pressure=0.042 mmHg, molecular weight=212.2)

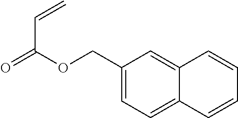 [SMILES: C=CC(=O)OCc1ccc2ccccc2c1]

4-cyanobenzyl acrylate (CNBzA, OP=2.44, boiling point=316° C., molecular weight=187)

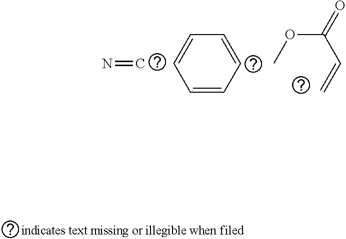

DVBzA indicated by the formula below (OP=2.50, boiling point=304.6° C., 80° C. vapor pressure=0.0848 mmHg, molecular weight=214.3)

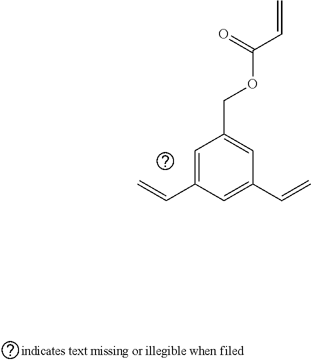 [SMILES: C=CC(=O)OCc1cc(C=C)cc(C=C)c1]

DPhPA indicated by the formula below (OP=2.38, boiling point=354.5° C., 80° C. vapor pressure=0.0022 mmHg, molecular weight=266.3)

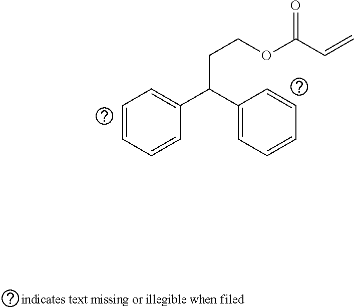 [SMILES: C=CC(=O)OCCC(c1ccccc1)c1ccccc1]

PhBzA indicated by the formula below (OP=2.29, boiling point=350.4° C., 80° C. vapor pressure=0.0022 mmHg, molecular weight=238.3)

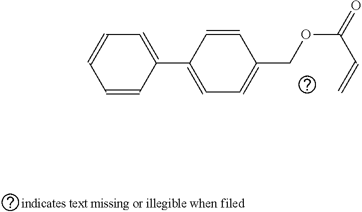 [SMILES: C=CC(=O)OCc1ccc(-c2ccccc2)cc1]

FLMA indicated by the formula below (OP=2.20, boiling point=349.3° C., 80° C. vapor pressure=0.0018 mmHg, molecular weight=250.3)

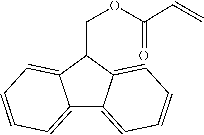 [SMILES: C=CC(=O)OCC1c2ccccc2-c2ccccc21]

ATMA indicated by the formula below (OP=2.13, boiling point=414.9° C., 80° C. vapor pressure=0.0001 mmHg, molecular weight=262.3)

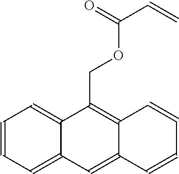 [SMILES: C=CC(=O)OCc1c2ccccc2cc2ccccc12]

DNaMA indicated by the formula below (OP=2.00, boiling point=489.4° C., 80° C. vapor pressure<0.0001 mmHg, molecular weight=338.4)

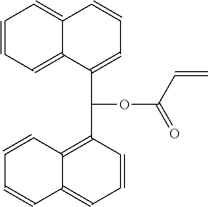 [SMILES: C=CC(=O)OC(c1cccc2ccccc12)c1cccc2ccccc12]

tricyclodecanedimethanol diacrylate (DCPDA, OP=3.29, boiling point=342° C., 80° C. vapor pressure<0.0024 mmHg, molecular weight=304)

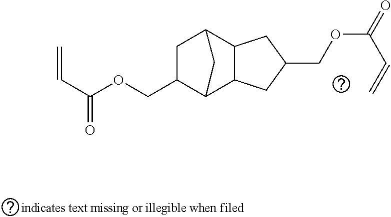 [SMILES: C=CC(=O)OCC1CC2C3CC(COC(=O)C=C)C(C3)C2C1]

m-xylylene diacrylate (mXDA, OP=3.20, boiling point=336° C., 80° C. vapor pressure<0.0043 mmHg, molecular weight=246)

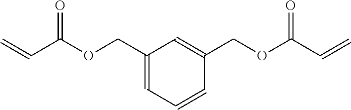 [SMILES: C=CC(=O)OCc1cccc(COC(=O)C=C)c1]

1-phenylethane-1,2-diyl diacrylate (PhEDA, OP=3.20, 80° C. vapor pressure<0.0057 mmHg, boiling point=354° C., molecular weight=246)

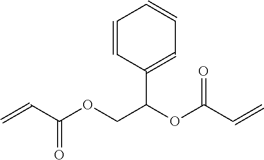 [SMILES: C=CC(=O)OCC(OC(=O)C=C)c1ccccc1]

2-phenyl-1,3-propan diol diacrylate (PhPDA, OP=3.18, boiling point=340° C., 80° C. vapor pressure<0.0017 mmHg, molecular weight=260)

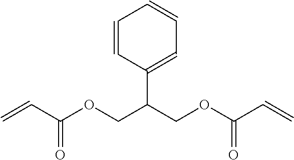 [SMILES: C=CC(=O)OCC(COC(=O)C=C)c1ccccc1]

VmXDA indicated by the formula below (OP=3.00, boiling point=372.4° C., 80° C. vapor pressure=0.0005 mmHg, molecular weight=272.3)

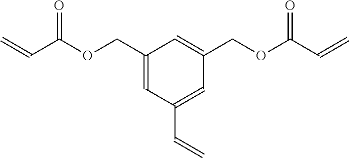 [SMILES: C=CC(=O)OCc1cc(C=C)cc(COC(=O)C=C)c1]

BPh44DA indicated by the formula below (OP=2.63, boiling point=444° C., 80° C. vapor pressure<0.0001 mmHg, molecular weight=322.3)

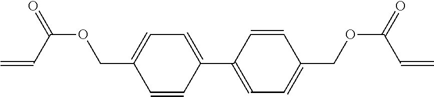 [SMILES: C=CC(=O)OCc1ccc(-c2ccc(COC(=O)C=C)cc2)cc1]

BPh43DA indicated by the formula below (OP=2.63, boiling point=439.5° C., 80° C. vapor pressure<0.0001 mmHg, molecular weight=322.3)

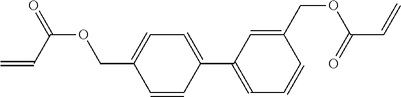 [SMILES: C=CC(=O)OCc1ccc(-c2cccc(COC(=O)C=C)c2)cc1]

DPhEDA indicated by the formula below (OP=2.63, boiling point=410° C., 80° C. vapor pressure<0.0001 mmHg, molecular weight=322.3)

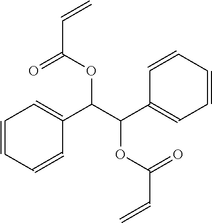 [SMILES: C=CC(=O)OC(c1ccccc1)C(OC(=O)C=C)c1ccccc1]

BPMDA indicated by the formula below (OP=2.68, boiling point=465.7° C., 80° C. vapor pressure<0.0001 mmHg, molecular weight=364.4)

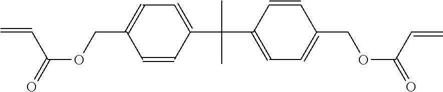 [SMILES: C=CC(=O)OCc1ccc(C(C)(C)c2ccc(COC(=O)C=C)cc2)cc1]

Na13MDA indicated by the formula below (OP=2.71, boiling point=438.8° C., 80° C. vapor pressure<0.0001 mmHg, molecular weight=296.3)

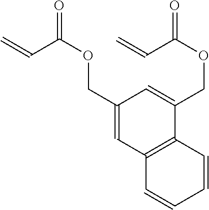 [SMILES: C=CC(=O)OCc1cc(COC(=O)C=C)c2ccccc2c1]

The amount of the component (as) or the component (af) in the component (a) is preferably 1 wt % or more and 99 wt % or less. The amount of the component (as) or the component (af) is more preferably 50 wt % or more and 95 wt % or less, and further preferably 60 wt % or more and 90 wt % or less.

At least a part of the component (a) which may include a plurality of types of additive components can be polymers having a polymerizable functional group. The polymer preferably contains at least a cyclic structure such as an aromatic structure, an aromatic heterocyclic structure, or an alicyclic structure. For example, the polymer preferably contains at least one of constituent units represented by formulas (3) to (8) below:

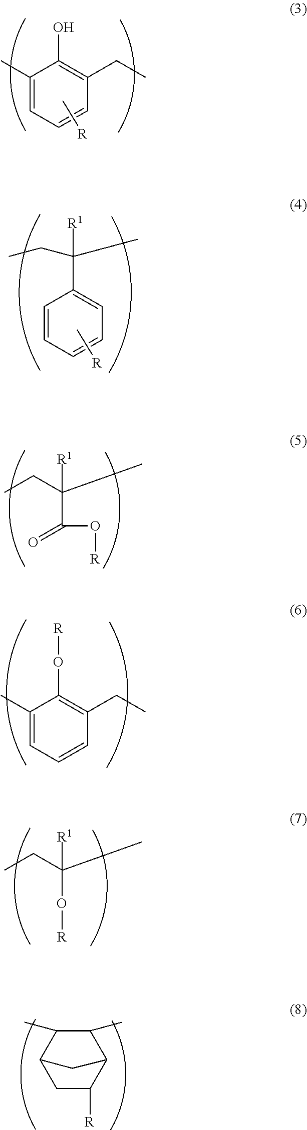

In the formulas (3) to (8), a substituent group R is a substituent group containing partial structures each independently containing an aromatic ring, and R¹ is a hydrogen atom or a methyl group. In this specification, in constituent units represented by the formulas (3) to (8), a portion other than R is the main chain of a specific polymer. The formula weight of the substituent group R is 80 or more, preferably 100 or more, more preferably 130 or more, and further preferably 150 or more. The upper limit of the formula weight of the substituent group R is practically 500 or less.

A polymer having a polymerizable functional group is normally a compound having a weight-average molecular weight of 500 or more. The weight-average molecular weight is preferably 1,000 or more, and more preferably 2,000 or more. The upper limit of the weight-average molecular weight is not particularly determined, but is preferably, for example, 50,000 or less. When the weight-average molecular weight is set at the above-described lower limit or more, it is possible to set the boiling point at 250° C. or more, and further improve the mechanical properties after curing. Also, when the weight-average molecular weight is set at the above-described upper limit or less, the solubility to the solvent increases, and the flowability of discretely arranged droplets is maintained because the viscosity is not too high. This makes it possible to further improve the flatness of the liquid film surface. Note that the weight-average molecular weight (Mw) in the present invention is a molecular weight measured by gel permeation chromatography (GPC), unless it is specifically stated otherwise.

Practical examples of the polymerizable functional group of the polymer are a (meth)acryloyl group, an epoxy group, an oxetane group, a methylol group, a methylol ether group, and a vinyl ether group. A (meth)acryloyl group is particularly favorable from the viewpoint of polymerization easiness. When adding the polymer having the polymerizable functional group as at least a part of the component (a), the blending ratio can freely be set as long as the blending ratio falls within the range of the viscosity regulation to be described later. For example, the blending ratio of polymer to the total mass of all the components except for the solvent (c) is preferably 0.1 wt % or more and 60 wt % or less, more preferably 1 wt % or more and 50 wt % or less, and further preferably 10 wt % or more and 40 wt % or less. When the blending ratio of the polymer having the polymerizable functional group is set at 0.1 wt % or more, it is possible to improve the heat resistance, the dry etching resistance, the mechanical strength, and the low volatility. Also, when the blending ratio of the polymer having the polymerizable functional group is set at 60 wt % or less, it is possible to make the blending ratio fall within the range of the upper limit regulation of the viscosity (to be described later).

### <Component (b): Photopolymerization Initiator>

The component (b) is a photopolymerization initiator. In this specification, the photopolymerization initiator is a compound that senses light having a predetermined wavelength and generates a polymerizing factor (radical) described earlier. More specifically, the photopolymerization initiator is a polymerization initiator (radical generator) that generates a radical by light (infrared light, visible light, ultraviolet light, far-ultraviolet light, X-ray, a charged particle beam such as an electron beam, or radiation). The component (b) can be formed by only one type of a photopolymerization initiator, and can also be formed by a plurality of types of photopolymerization initiators.

Examples of the radical generator are as follows, but the radical generator is not limited to these examples. 2,4,5-triarylimidazole dimers that can have substituent groups, such as a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, and a 2-(o- or p-methoxyphenyl)-4,5-diphenylimidazole dimer; benzophenone derivatives such as benzophenone, N,N′-tetramethyl-4,4′-diaminobenzophenone (Michiler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; α-amino aromatic ketone derivatives such as 2-benzyl-2-dimethylamino-1-(4-morpholinophenyl)-butanone-1,2-methyl-1-[4-(methylthio)phenyl]-2-morpholino-propane-1-one; quinones such as 2-ethylanthraquinone, phenanthrenequinone, 2-t-butylanthraquinone, octamethylanthraquinone, 1,2-benzanthraquinone, 2,3-benzanthraquinone, 2-phenylanthraquinone, 2,3-diphenylamthraquinone, 1-chloroanthraquinone, 2-methylanthraquinone, 1,4-naphtoquinone, 9,10-phenanthraquinone, 2-methyl-1,4-naphtoquinone, and 2,3-dimethylanthraquinone; benzoin ether derivatives such as benzoin methyl ether, benzoin ethyl ether, and benzoin phenyl ether; benzoin derivatives such as benzoin, methyl benzoin, ethyl benzoin, and propyl benzoin; benzyl derivatives such as benzyldimethylketal; acridine derivatives such as 9-phenylacridine and 1,7-bis(9,9′-acrydinyl)heptane; N-phenylglycine derivatives such as N-phenylglycine; acetophenone derivatives such as acetophenone, 3-methylacetophenone, acetophenone benzylketal, 1-hydroxycylohexyl phenylketone, and 2,2-dimethoxy-2-phenyl acetophenone; thioxanthone derivatives such as thioxanthone, diethylthioxanthone, 2-isopropylthioxanthone, and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthiol)-,2-(O-benzoyloxime)], ethanone, 1-[9-ethyl-6-(2-methylbenzoyl)-9H-carbazole-3-yl]-, and 1-(0-acetyloxime); and xanthone, fluorenone, benzaldehyde, fluorene, anthraquinone, triphenylamine, carbazole, 1-(4-isopropylphenyl)-2-hydroxy-2-methylprapane-1-one, and 2-hydroxy-2-methyl-1-phenylpropane-1-one.

Examples of the commercially available products of the above-described radical generators are as follows, but the products are not limited to these examples. Irgacure 184, 369, 651, 500, 819, 907, 784, and 2959, CGI-1700, -1750, and -1850, CG24-61, Darocur 1116 and 1173, Lucirin® TPO, LR8893, and LR8970 (manufactured by BASF), and Ubecryl P36 (manufactured by UCB).

Of the above-described radical generators, the component (b) is preferably an acylphosphine oxide-based polymerization initiator. Note that of the above-described radical generators, the acylphosphine oxide-based polymerization initiators are as follows.
Acylphosphine oxide compounds such as 2,4,6-trimethylbenzoyl diphenylphosphine oxide, bis(2,4,6-trimethylbenzoyl)phenylphosphine oxide, and bis(2,6-dimethoxybenzoyl)-2,4,4-trimethylpentylphosphine oxide.

The blending ratio of the component (b) in the curable composition (A) is preferably 0.1 wt % or more and 50 wt % or less with respect to the sum of the component (a), the component (b), and a component (d) (to be described later), that is, the total mass of all the components except for the solvent (c). Also, the blending ratio of the component (b) in the curable composition (A) is more preferably 0.1 wt % or more and 20 wt % or less, and further preferably 1 wt % or more and 20 wt % or less with respect to the total mass of all the components except for the solvent (d). When the blending ratio of the component (b) is set at 0.1 wt % or more, the curing rate of the composition increases, so the reaction efficiency can be improved. Also, when the blending ratio of the component (b) is set at 50 wt % or less, a cured film having mechanical strength to some extent can be obtained.

### <Component (c): Solvent>

The curable composition (A) contains, as the component (c), a solvent having a boiling point of 135° C. or more and less than 250° C. at normal pressure and a surface tension of 24 [mN/m] or less at normal temperature. The component (c) contains, for example, silicon atoms or fluorine atoms at 10 at % or less. The component (c) is a solvent that dissolves the components (a), (b), and (d), and examples are an ether hydrocarbon solvent, a perfluorocarbon solvent, an alcoholic fluorinated solvent, an ester-based fluorinated solvent, and a halogenated fluorinated solvent.

Another example of the component (c) is polyhydric alcohol ether obtained by alkyl-etherifying all hydroxyl groups of polyhydric alcohol ether.

Still other examples of the component (c) are ethylene glycol ditertiary butyl ether or diethylene glycol methyl tertiary butyl ether. It is possible to use one type of the component (c) alone, or use two or more types of components (c) in combination. The boiling point of the component (c) at normal pressure is 130° C. or more, preferably 145° C. or more and particularly preferably 150° C. or more. The boiling point of the component (c) at normal pressure is less than 250° C., and preferably 200° C. or less. As described above, the boiling point of the component (c) at normal pressure is 130° C. or more and less than 250° C. If the boiling point of the component (c) at normal pressure is less than 130° C., drying progresses near an ink jet nozzle, resulting in a discharge failure such as clogging or distortion. Also, since the volatilization speed in the waiting step to be described later is too high, the component (c) may volatilize before the droplets of the curable composition (A) combine with each other, and the droplets of the curable composition (A) may not combine. On the other hand, if the boiling point of the component (c) at normal pressure is 250° C. or more, the discharge failure such as clogging or distortion is improved. However, in the waiting step to be described later, volatilization of the solvent (c) is insufficient, and the component (c) may remain in the cured product of the curable composition (A).

Examples of the ether hydrocarbon solvent are as follows. ethylene glycol di-tert-butyl ether, diethylene glycol methyl-tert-butyl ether, MFDG-tBu (manufactured by NIPPON NYUKAZAI)

Examples of the perfluorocarbon solvent are as follows. FC-40, FC-43 (manufactured by 3M)

Examples of alcoholic fluorinated solvent are as follows. 3-(perfluorobutyl)propanol, 3-(perfluorohexyl)propanol, 2,2,3,3,4,4,5,5-octafluoro-1,6-hexanediol

Example of the ester-based fluorinated solvent is as follows. ethyl 5H-octafluoropentanoate

Examples of the halogenated fluorinated solvent are as follows. 2-(perfluorobutyl)ethyl iodide, 2-(perfluorohexyl)ethyl iodide, octafluoro-1,4-diiodobutane, dodecafluoro-1,6-diiodohexane, 1-bromoheptafluoroctane

Among the above-described solvents, the ether hydrocarbon solvent, the perfluorocarbon solvent, the ester-based fluorinated solvent, and the halogenated fluorinated solvent are preferable.

Further favorable examples of the solvent are as follows. ethylene glycol di-tert-butyl ether, diethylene glycol methyl-tert-butyl ether

In the present invention, if the surface tension of the curable composition in a state in which the solvent (c) is removed is γ1 [mN/m], and the surface tension of the solvent (c) at 23° C. is γ2 [mN/m], the curable composition is configured such that γ1 is larger than γ2. In other words, when Δγ=γ1-γ2, the curable composition is configured such that Δγ is larger than zero. More specifically, the solvent (c) is selected such that Δγ is larger than zero. If Δγ is larger than zero, in the waiting step to be described later, spread of each droplet of the curable composition is accelerated by the Marangoni effect, and the droplets quickly combine with each other to form a continuous liquid film. In addition, since volatilization of the solvent is accelerated by the quick spread of the droplets, the waiting step to be described later is completed in a short time, or the conditions of a baking step are relaxed or omitted. Δγ is preferably 0.1 or more (γ1-γ2>0.1 [mN/m]), particularly, preferably 1.0 or more (γ1-γ2>1 [mN/m]), and further preferably 2.0 or more. Note that γ1 and γ2 are each a surface tension at normal pressure (1 atm).

In the present invention, a polymerizable compound having a boiling point of 80° C. or more and less than 250° C. at normal pressure is also usable as the component (d). Examples of the polymerizable compound having a boiling point of 80° C. or more and less than 250° C. at normal pressure are as follows.

Cyclohexyl acrylate (198° C.), benzyl acrylate (229° C.), isobornyl acrylate (245° C.), tetrahydrofurfuryl acrylate (202° C.), trimethylcyclohexyl acrylate (232° C.), isooctyl acrylate (217° C.), n-octyl acrylate (228° C.), ethoxyethoxyethyl acrylate (230° C.), divinylbenzene (193° C.), 1,3-diisopropenylbenzene (218° C.), styrene (145° C.), and α-methylstyrene (165° C.).

In the present invention, when the whole of the curable composition (A) is 100 vol %, the content of the solvent (c) is 5 vol % or more and 95 vol % or less, preferably 70 vol % or more and 85 vol % or less, and further preferably 70 vol % or more and 80 vol % or less. If the content of the solvent (c) is smaller than 5 vol %, a thin film cannot be obtained after volatilization of the solvent (c) under conditions for obtaining a practically continuous liquid film. Also, if the content of the solvent (c) is larger than 95 vol %, it is difficult to obtain a thick film after the solvent (d) volatilized even when droplets are densely dropped by an inkjet method.

### <Component (d): Nonpolymerizable Compound>

In addition to the components (a) and (b) described above, the curable composition (A) can further contain a nonpolymerizable compound as the component (d). An example of the component (d) is a compound that does not contain a polymerizable functional group such as a (meth)acryloyl group, and does not have the ability to sense light having a predetermined wavelength and generate the polymerizing factor (radical) described previously. Examples of the nonpolymerizable compound are a sensitizer, a hydrogen donor, an internal mold release agent, an antioxidant, a polymer component, and other additives. The component (d) can contain a plurality of types of the above-described compounds.

The sensitizer is a compound that is properly added for the purpose of promoting the polymerization reaction and improving the reaction conversion rate. As the sensitizer, it is possible to use one type of a compound alone, or to use two or more types of compounds by mixing them.

An example of the sensitizer is a sensitizing dye. The sensitizing dye is a compound that is excited by absorbing light having a specific wavelength and has an interaction with a photopolymerization initiator as the component (b).

The “interaction” herein mentioned is energy transfer or electron transfer from the sensitizing dye in the excited state to the photopolymerization initiator as the component (b). Practical examples of the sensitizing dye are as follows, but the sensitizing dye is not limited to these examples.

An anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridinic dye, a thiopyrylium salt-based dye, a merocyanine-based dye, a quinoline-based dye, a styryl quinoline-based dye, a ketocoumarin-based dye, a thioxanthene-based dye, a xanthene-based dye, an oxonol-based dye, a cyanine-based dye, a rhodamine-based dye, and a pyrylium salt-based dye.

The hydrogen donor is a compound that reacts with an initiation radical generated from the photopolymerization initiator as the component (b) or a radical at a polymerization growth end, and generates a radical having higher reactivity. The hydrogen donor is preferably added when the photopolymerization initiator as the component (b) is a photo-radical generator.

Practical examples of the hydrogen donor as described above are as follows, but the hydrogen donor is not limited to these examples. amine compounds such as n-butylamine, di-n-butylamine, tri-n-butylphosphine, allylthiourea, s-benzylisothiuronium-p-toluenesulfinate, triethylamine, diethylaminoethyl methacrylate, triethylenetetramine, 4,4′-bis(dialkylamino)benzophenone, N,N-dimethylamino ethylester benzoate, N,N-dimethylamino isoamylester benzoate, pentyl-4-dimethylamino benzoate, triethanolamine, and N-phenylglycine; and mercapto compounds such as 2-mercapto-N-phenylbenzoimidazole and mercapto propionate ester.

It is possible to use one type of a hydrogen donor alone, or to use two or more types of hydrogen donors by mixing them. The hydrogen donor can also have a function as a sensitizer.

An internal mold release agent can be added to the curable composition for the purpose of reducing the interface bonding force between a mold and the curable composition, that is, reducing the mold release force in a mold release step (to be described later). In this specification, “internal” means that the mold release agent is added to the curable composition in advance before a curable composition arranging step. As the internal mold release agent, it is possible to use surfactants such as a silicon-based surfactant, a fluorine-based surfactant, and a hydrocarbon-based surfactant. In the present invention, however, the addition amount of the fluorine-based surfactant is limited as will be described later. Note that the internal mold release agent according to the present invention is not polymerizable. It is possible to use one type of an internal mold release agent alone, or to use two or more types of internal mold release agents by mixing them.

The fluorine-based surfactant includes the following. A polyalkylene oxide (for example, polyethylene oxide or polypropylene oxide) adduct of alcohol having a perfluoroalkyl group, and a polyalkylene oxide (for example, polyethylene oxide or polypropylene oxide) adduct of perfluoropolyether.

Note that the fluorine-based surfactant can have a hydroxyl group, an alkoxy group, an alkyl group, an amino group, or a thiol group in a portion (for example, a terminal group) of the molecular structure. An example is pentadecaethyleneglycol monolH,1H,2H,2H-perfluorooctylether.

It is also possible to use a commercially available product as the fluorine-based surfactant. Examples of the commercially available product of the fluorine-based surfactant are as follows.
MEGAFACE® F-444, TF-2066, TF-2067, and TF-2068, and DEO-15 (abbreviation) (manufactured by DIC) Fluorad FC-430 and FC-431 (manufactured by Sumitomo 3M)
Surflon® S-382 (manufactured by AGC); EFTOP EF-122A, 122B, 122C, EF-121,
EF-126, EF-127, and MF-100 (manufactured by Tochem Products)
PF-636, PF-6320, PF-656, and PF-6520 (manufactured by OMNOVA Solutions)
UNIDYNE® DS-401, DS-403, and DS-451 (manufactured by DAIKIN)
FUTAGENT® 250, 251, 222F, and 208G (manufactured by NEOS).

The internal mold release agent can also be a hydrocarbon-based surfactant. The hydrocarbon-based surfactant includes an alkyl alcohol polyalkylene oxide adduct obtained by adding alkylene oxide having a carbon number of 2 to 4 to alkyl alcohol having a carbon number of 1 to 50, and polyalkylene oxide.

Examples of the alkyl alcohol polyalkylene oxide adduct are as follows. A methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, and a stearyl alcohol ethylene oxide/propylene oxide adduct.

Note that the terminal group of the alkyl alcohol polyalkylene oxide adduct is not limited to a hydroxyl group that can be manufactured by simply adding polyalkylene oxide to alkyl alcohol. This hydroxyl group can also be substituted by a polar functional group such as a carboxyl group, an amino group, a pyridyl group, a thiol group, or a silanol group, or by a hydrophobic group such as an alkyl group or an alkoxy group.

Examples of the polyalkylene oxide are as follows. polyethylene glycol, polypropylene glycol, their mono or dimethyl ether, mono or dioctyl ether, mono or dinonyl ether, and mono or didecyl ether, monoadipate, monooleate, monostearate, and monosuccinate.

A commercially available product can also be used as the alkyl alcohol polyalkylene oxide adduct. Examples of the commercially available product of the alkyl alcohol polyalkylene oxide adduct are as follows. polyoxyethylene methyl ether (a methyl alcohol ethylene oxide adduct) (BLAUNON MP-400, MP-550, and MP-1000) manufactured by AOKI OIL INDUSTRIAL, polyoxyethylene decyl ether (a decyl alcohol ethylene oxide adduct) (FINESURF D-1303, D-1305, D-1307, and D-1310) manufactured by AOKI OIL INDUSTRIAL, polyoxyethylene lauryl ether (a lauryl alcohol ethylene oxide adduct) (BLAUNON EL-1505) manufactured by AOKI OIL INDUSTRIAL, polyoxyethylene cetyl ether (a cetyl alcohol ethylene oxide adduct) (BLAUNON CH-305 and CH-310) manufactured by AOKI OIL INDUSTRIAL, polyoxyethylene stearyl ether (a stearyl alcohol ethylene oxide adduct) (BLAUNON SR-705, SR-707, SR-715, SR-720, SR-730, and SR-750) manufactured by AOKI OIL INDUSTRIAL, randomly polymerized polyoxyethylene polyoxypropylene stearyl ether (BLAUNON SA-50/50 1000R and SA-30/70 2000R) manufactured by AOKI OIL INDUSTRIAL, polyoxyethylene methyl ether (Pluriol® A760E) manufactured by BASF, and polyoxyethylene alkyl ether (EMULGEN series) manufactured by KAO.

A commercially available product can also be used as polyalkylene oxide. An example is an ethylene oxide/propylene oxide copolymer (Pluronic PE6400) manufactured by BASF.

The fluorine-based surfactant has an excellent mold release force reducing effect and hence is effective as an internal mold release agent. The blending ratio of the component (d) in the curable composition (A) except for the fluorine-based surfactant is preferably 0 wt % or more and 50 wt % or less with respect to the sum of the components (a), (b), and (d), that is, the total mass of all the components except for the solvent (c). The blending ratio of the component (d) in the curable composition (A) except for the fluorine-based surfactant is more preferably 0.1 wt % or more and 50 wt % or less, and further preferably 0.1 wt % or more and 20 wt % or less with respect to the total mass of all the components except for the solvent (c). When the blending ratio of the component (d) except for the fluorine-based surfactant is set at 50 wt % or less, a cured film having mechanical strength to some extent can be obtained.

### <Temperature When Blending Curable Composition>

When preparing the curable composition (A), at least the components (a), (b), and (c) are mixed and dissolved under a predetermined temperature condition.

More specifically, the predetermined temperature condition is 0° C. or more and 100° C. or less. Note that the same applies to a case in which the curable composition (A) contains the component (d).

### <Viscosity of Curable Composition>

The curable composition (A) is a liquid. This is so because droplets of the curable composition (A) are discretely dropped on a substrate by an inkjet method in an arranging step (to be described later). At 23° C. and at 1 atm, the viscosity of the curable composition (A) is 1.3 mPa·s or more and 60 mPa·s or less, preferably 3 mPa·s or more and 30 mPa·s or less, and further preferably 3 mPa·s or more and 15 mPa·s or less. If the viscosity of the curable composition (A) is smaller than 1.3 mPa·s, the discharge property of droplets by an inkjet method becomes unstable. Also, if the viscosity of the curable composition (A) is larger than 60 mPa·s, it is difficult to form droplets having a volume of about 1.0 to 3.0 pL favorable in the present invention.

The viscosity of the composition at 23° C. and at 1 atm in a state after the solvent (c) is volatilized from the curable composition (A), that is, in a state in which the solvent (c) is removed is 30 mPa·s or more and 10,000 mPa·s or less.

The viscosity of the composition at 23° C. and at 1 atm in a state in which the solvent (c) is removed is preferably 90 mPa·s or more and 2,000 mPa·s or less, for example, 120 mPa·s or more and 1,000 mPa·s or less. The viscosity of the composition at 23° C. and at 1 atm in a state in which the solvent (c) is removed is further preferably 200 mPa·s or more and 500 mPa·s or less. The composition in a state in which the solvent (c) is removed is also expressed as a curable composition (A′). When the viscosity of the curable composition (A′) at 23° C. is set to 1,000 mPa·s or less, spreading and filling are rapidly completed when bringing the curable composition (A′) into contact with a mold. Accordingly, the use of the curable composition (A) makes it possible to perform an imprinting process at high throughput, and suppress pattern defects caused by insufficient filling. Also, when the viscosity of the curable composition (A′) at 23° C. is set to 30 mPa·s or more, it is possible to prevent an unnecessary flow of droplets of the curable composition (A′). Furthermore, when bringing the curable composition (A′) into contact with a mold, flow-out of the curable composition (A′) from the end portions of the mold can be suppressed.

### <Surface Tension of Curable Composition>

The curable composition (A) in a state in which the solvent (component (c)) is removed has a surface tension of 5 mN/m or more and 30 mN/m or less at 23° C. and at 1 atm. At 23° C. and at 1 atm, the curable composition (A) in a state in which the solvent (component (c)) is removed more preferably has a surface tension of 7 mN/m or more and 28 mN/m or less, and further preferably has a surface tension of 10 mN/m or more and 26 mN/m or less. In other words, the curable composition (A′) preferably has a surface tension of 5 mN/m or more and 30 mN/m or less, more preferably has a surface tension of 7 mN/m or more and 28 mN/m or less, and further preferably has a surface tension of 10 mN/m or more and 28 mN/m or less. Note that when the surface tension is high, for example, 5 mN/m or more, the capillarity strongly acts, so filling (spreading and filling) is complete within a short time period when the curable composition (A) and a mold are brought into contact with each other. Also, when the surface tension is 30 mN/m or less, a cured film obtained by curing the curable composition has surface smoothness.

### <Contact Angle of Curable Composition>

The contact angle of the curable composition (A) in a state in which the solvent (component (c)) is removed is preferably 0° or more and 900 or less and particularly preferably 0° or more and 10° or less with respect to both the surface of a substrate and the surface of a mold. In other words, the contact angle of the curable composition (A′) is preferably 0° or more and 90° or less, and particularly preferably 0° or more and 100 or less. If the contact angle is larger than 90°, the capillarity acts in a negative direction (a direction in which the contact interface between the mold and the curable composition is shrunk) inside a pattern of the mold or in a gap between the substrate and the mold, and the mold may not be filled with the curable composition (A). When the contact angle is small, the capillarity strongly acts, and the filling rate increases.

### <Impurities Mixed in Curable Composition>

The curable composition (A) preferably contains impurities as little as possible. Note that impurities mean components other than the components (as), (a), (b), (c), and (d) described above. Therefore, the curable composition (A) is favorably a composition obtained through a refining step. A refining step like this is preferably filtration using a filter.

As this filtration using a filter, it is favorable to mix the components (a), (b), and (c) described above, and filtrate the mixture by using, for example, a filter having a pore diameter of 0.001 μm or more and 5.0 μm or less. When performing filtration using a filter, is it further favorable to perform the filtration in multiple stages, or to repetitively perform the filtration a plurality of times (cycle filtration). It is also possible to re-filtrate a liquid once filtrated through a filter, or perform filtration by using filters having different pore diameters. Examples of the filter for use in filtration are filters made of, for example, a polyethylene resin, a polypropylene resin, a fluorine resin, and a nylon resin, but the filter is not particularly limited. Impurities such as particles mixed in the curable composition can be removed through the refining step as described above. Consequently, it is possible to prevent impurities mixed in the curable composition from causing pattern defects by forming unexpected unevenness on a cured film obtained after the curable composition is cured.

Note that when using the curable composition (A) in order to fabricate a semiconductor integrated circuit, it is favorable to avoid mixing of impurities (metal impurities) containing metal atoms in the curable composition as much as possible so as not to obstruct the operation of a product. The concentration of the metal impurities contained in the curable composition is preferably 10 ppm or less, and more preferably 100 ppb or less.

### [Dropping Member]

In this specification, a member (dropping member) on which the droplets of the curable composition (A) are discretely dropped will be described as a substrate (mold base material) or a mold (master mold).

The mold base material is made of, for example, quartz. The mold base material may have an adhesive layer on the surface. However, the mold base material is not limited to quartz. For example, the mold base material can freely be selected from those known as semiconductor device substrates such as silicon, aluminum, a titanium-tungsten alloy, an aluminum-silicon alloy, an aluminum-copper-silicon alloy, silicon oxide, and silicon nitride. Note that the surface of the mold base material is preferably treated by a surface treatment such as a silane coupling treatment, a silazane treatment, or deposition of an organic thin film, thereby improving the adhesion to the curable composition (A). As a practical example of the organic thin film to be deposited as the surface treatment, an adhesive layer described in Japanese Patent Laid-Open No. 2009-503139 can be used.

### [First Pattern Forming Method]

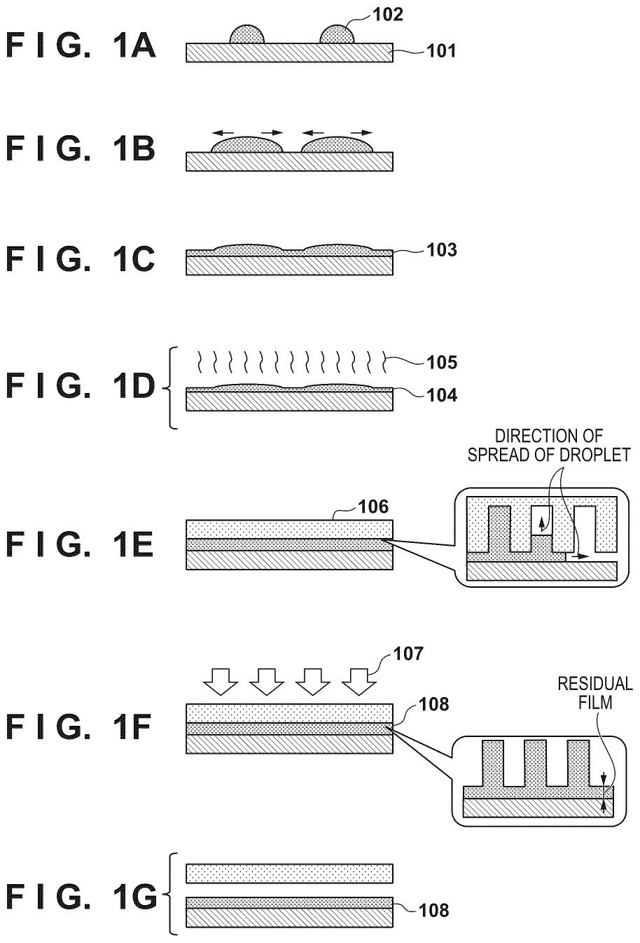

A first pattern forming method according to the present invention will be described with reference to FIGS. 1A to 1G. In the first pattern forming method, a member to which the droplets of the curable composition (A) are discretely dropped is a mold base material. The cured film formed by the present invention is preferably a film having a pattern with a size of 1 nm or more and 10 mm or less, and more preferably a film having a pattern with a size of 10 nm or more and 100 μm or less. In general, a film forming method of forming a film having a pattern (concave-convex structure) with a nanosize (1 nm or more and 100 nm or less) using light is called a photoimprint method. The film forming method of the present invention forms a film of a curable composition in a space between a mold base material and a master mold by using the photoimprint method. However, the curable composition can also be cured by another energy (for example, heat or an electromagnetic wave). Also, the film forming method according to the present invention may be executed as a method of forming a film having a pattern, that is, a pattern forming method, or may be executed as a method of forming a film having no pattern (for example, a flat film), that is, a flat film forming method.

An example in which film forming method according to the present invention is applied to the first pattern forming method will be described below. The first pattern forming method includes, for example, a preparation step, an arranging step, a waiting step, a contact step, a curing step, and a mold release step. The preparation step is a step of preparing an underlayer. The arranging step is a step of discretely arranging the droplets of the curable composition (A) on the underlayer. The waiting step is a step of waiting until the droplets of the curable composition (A) combine with each other, and the solvent (c) volatilizes.

The contact step is a step of bringing the curable composition (A or A′), preferably the curable composition (A′) into contact with the master mold. The curing step is a step of curing the curable composition (A or A′), preferably the curable composition (A′). The mold release step is a step of releasing the master mold from the cured film of the curable composition (A or A′). The arranging step is executed after the preparation step, the waiting step is executed after the arranging step, the contact step is executed after the waiting step, the curing step is executed after the contact step, and the mold release step is executed after the curing step.

### <Arranging Step>

In the arranging step, as schematically shown in FIG. 1A, droplets 102 of the curable composition (A) are discretely arranged on a mold base material 101.

As an arranging method of arranging the droplets 102 of the curable composition (A) on the mold base material, an inkjet method is particularly preferable. The droplets 102 of the curable composition (A) are densely arranged on a region of the mold base material 101 facing a region where concave portions that form the pattern of a master mold 106 densely exist. In addition, the droplets 102 of the curable composition (A) are coarsely arranged on a region of the mold base material 101 facing a region where concave portions that form the pattern of the master mold 106 coarsely exist. Hence, the film (residual film) of the curable composition (A) (to be described later), which is formed on the mold base material 101, can be controlled to an even thickness regardless of whether the pattern of the master mold 106 is dense or coarse.

To define the volume of the curable composition (A) to be arranged on the mold base material, an index called an average liquid film thickness is defined. The average liquid film thickness is a value obtained by dividing the volume of the curable composition (A) (except for the solvent (c)) arranged in the arranging step by the area of the film formation region of the master mold. The volume of the cured product or cured film of the curable composition (A) (except for the solvent (c)) is the sum of the volumes of the droplets of the curable composition (A) after volatilization of the solvent (c). According to this definition, even if the surface of the mold base material has a concave-convex pattern, the average liquid film thickness can be defined regardless of the concave-convex state.

### <Waiting Step>

In the present invention, the waiting step is provided after the arranging step and before the contact step (between the arranging step and the contact step). Here, a value obtained by dividing the total volume of the droplets of the curable composition (A) dropped in one pattern formation by the total area of the region (film formation region) where a pattern is formed by one pattern formation is defined as an average film thickness. In the waiting step, the droplets 102 of the curable composition (A) spread on the mold base material 101, as schematically shown in FIG. 1B. The whole pattern formation region of the mold base material 101 is covered with the curable composition (A). If the average film thickness is 130 nm or more, as schematically shown in FIG. 1C, the droplets of the curable composition (A) combine with each other on the mold base material, and a practically continuous liquid film 103 is formed. If the average film thickness is 150 nm or more, the surface of the liquid film 103 is flat. The liquid film 103 having an average film thickness of 130 nm or more can be obtained by arranging the droplets 102 of the curable composition (A) having a volume of 1.0 pL or more at a density of 130 pieces/mm² or more. Similarly, the liquid film 103 having an average film thickness of 150 nm or more can be obtained by arranging the droplets 102 of the curable composition (A) having a volume of 1.0 pL or more at a density of 150 pieces/mm² or more. Note that in this embodiment, the average film thickness is preferably 10 μm or less, and particularly preferably 1 μm or less. If the average film thickness is larger than 10 μm, the stability of the pattern shape of a replica mold is low.

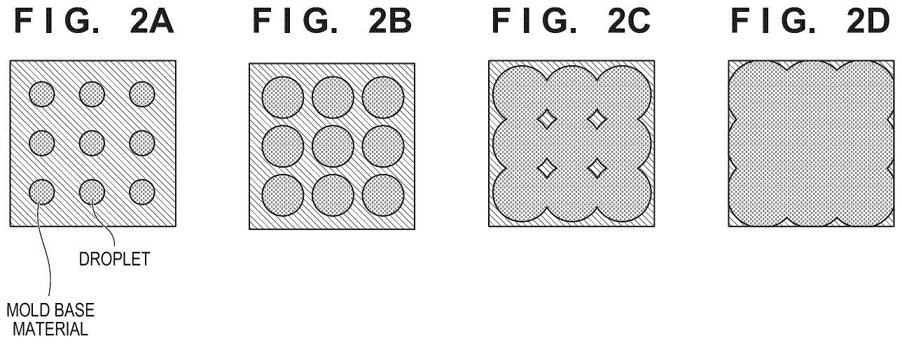

A flow behavior of the droplets of the curable composition (A) arranged on the mold base material during the waiting step will be explained with reference to FIGS. 2A to 2D. The droplets of the curable composition (A) are discretely arranged on the mold base material, as shown in FIG. 2A, and each droplet gradually spreads on the mold base material, as shown in FIG. 2B. Then, the droplets of the curable composition (A) on the mold base material begin combining with each other, as shown in FIG. 2C, and form a continuous liquid film, as shown in FIG. 2D (a state in which the surface of the mold base material is covered with the curable composition (A), and no exposed surface remains). The state of the curable composition (A) as shown in FIG. 2D is called “a practically continuous liquid film”.

Furthermore, in the waiting step, as schematically shown in FIG. 1D, a solvent 105 (solvent (c)) contained in the liquid film 103 is volatilized. Assuming that the total weight of the components except for the solvent (c) is 100 vol %, the residual amount of the solvent (c) in a liquid film 104 after the waiting step (for example, at the contact step) is preferably 10 vol % or less. If the residual amount of the solvent (c) is larger than 10 vol %, the mechanical properties of the cured film may deteriorate.

In the waiting step, it is possible to perform a baking step of heating the mold base material 101 and the curable composition (A), or ventilate the atmospheric gas around the mold base material 101, for the purpose of accelerating the volatilization of the solvent (c). The heating is performed at, for example, 30° C. or more and 200° C. or less, preferably 80° C. or more and 150° C. or less, and particularly preferably 90° C. or more and 110° C. or less. The heating time can be 10 sec or more and 600 sec or less. The baking step can be performed by using a known heater such as a hotplate or an oven.

The waiting step is, for example, 0.1 to 600 sec, and preferably 10 to 300 sec. If the waiting step is shorter than 0.1 sec, the combination of the droplets of the curable composition (A) becomes insufficient, so no practically continuous liquid film is formed. If the waiting step exceeds 600 sec, the productivity decreases. To suppress the decrease in productivity, therefore, it is also possible to sequentially move the mold base material completely processed in the arranging step to the waiting step, perform the waiting step in parallel to a plurality of mold base materials, and sequentially move the mold base materials completely processed in the waiting step to the contact step. Note that in the related art, a few thousands of seconds to a few tens of thousands of seconds are theoretically required before a practically continuous liquid film is formed. In practice, however, it is impossible to form a continuous liquid film because the spread of the droplets of the curable composition stagnates due to the influence of volatilization.

In the waiting step, when the solvent (c) volatilizes, the practically continuous liquid film 104 of a composition made of the components (as), (af), (a), (b), and (d), that is, the curable composition (A′) remains. The average film thickness of the practically continuous liquid film 104 of the curable composition (A) from which the solvent (c) is volatilized (removed), that is, the curable composition (A′) is smaller than that of the liquid film 103 by an amount of volatilization of the solvent (c). A state in which the pattern formation region of the mold base material 101 is wholly covered with the practically continuous liquid film 104 of the curable composition (A′) is maintained.

### <Contact Step>

In the contact step, as schematically shown in FIG. 1E, the practically continuous liquid film 104 of the curable composition (A) from which the solvent (c) is removed, that is, the curable composition (A′) is brought into contact with the master mold 106. The contact step includes a step of a changing a state in which the curable composition (A′) and the master mold 106 are not in contact with each other to a state in which they are in contact with each other, and a step of maintaining the state in which they are in contact with each other. As a consequence, the liquid of the curable composition (A′) is filled in the concave portions of fine patterns on the surface of the master mold 106, and the liquid forms a liquid film filled in the fine patterns of the master mold 106.

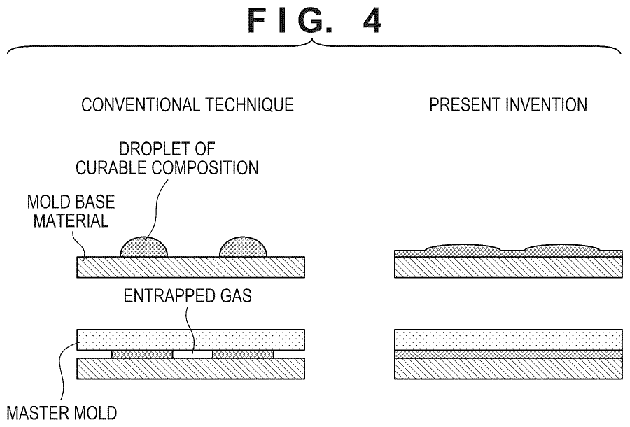

In the waiting step, since the solvent (c) is removed from the curable composition (A), and the practically continuous liquid film 104 of the curable composition (A′) is formed, the volume of a gas entrapped between the master mold 106 and the mold base material 101 is small. Hence, the spread of the curable composition (A′) in the contact step is quickly completed. FIG. 4 shows the comparison (difference) between the contact step in the related art disclosed in Japanese Patent No. 6584578 or the like and the contact step according to the present invention.

If the spread and filling of the curable composition (A′) are quickly completed in the contact step, the time for maintaining a state in which the master mold 106 is in contact with the curable composition (A′) (the time necessary for the contact step) can be shortened. Since shortening the time necessary for the contact step leads to shortening the time necessary for formation of a pattern (formation of a film), the productivity is improved. The contact step is preferably 0.1 sec or more and 3 sec or less, and particularly preferably 0.1 sec or more and 1 sec or less. If the contact step is shorter than 0.1 sec, spreading and filling become insufficient, so many defects called incomplete filling defects tend to occur.

If the curing step includes a photoirradiation step, a mold made of a light-transmitting material is preferably used as the master mold 106. Favorable examples of the type of the material forming the master mold 106 are glass, quartz, PMMA, a photo-transparent resin such as a polycarbonate resin, a transparent metal deposition film, a soft film such as polydimethylsiloxane, a photo-cured film, and a metal film. Note that when using the photo-transparent resin as the material forming the master mold 106, a resin that does not dissolve in components contained in a curable composition is selected. Quartz is suitable as the material forming the master mold 106 because the thermal expansion coefficient is small and pattern distortion is small.

A pattern formed on the surface of the master mold 106 has a height of, for example, 4 nm or more and 200 nm or less. As the pattern height of the master mold 106 decreases, it becomes possible to decrease the force of releasing the mold from the cured film of the curable composition, that is, the mold release force in the mold release step. Hence, it is possible to decrease the number of mold release defects remaining in the master mold 106 because the pattern of the curable composition is torn off. Also, in some cases, the pattern of the curable composition elastically deforms due to the impact when the master mold 106 is released, and adjacent pattern elements come in contact with each other and adhere to each other or break each other. Note that to avoid these problems, it is advantageous to make the height of pattern elements be about twice or less the width of the pattern elements (make the aspect ratio be 2 or less). On the other hand, if the height of pattern elements is too small, the processing accuracy of the mold base material 101 decreases.

A surface treatment can also be performed on the master mold 106 before performing the contact step, in order to improve the detachability of the master mold 106 with respect to the curable composition (A). An example of this surface treatment is to form a mold release agent layer by coating the surface of the master mold 106 with a mold release agent. Examples of the mold release agent to be applied on the surface of the master mold 106 are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone, or use two or more types of mold release agents together. Of the mold release agents described above, fluorine-based and hydrocarbon-based mold release agents are particularly favorable.

In the contact step, the pressure to be applied to the curable composition (A) when bringing the master mold 106 into contact with the curable composition (A) is not particularly limited, and is, for example, 0 MPa or more and 100 MPa or less. Note that when bringing the master mold 106 into contact with the curable composition (A), the pressure to be applied to the curable composition (A) is preferably 0 MPa or more and 50 MPa or less. Also, when bringing the master mold 106 into contact with the curable composition (A), the pressure to be applied to the curable composition (A) is more preferably 0 MPa or more and 30 MPa or less, and further preferably 0 MPa or more and 20 MPa or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

### <Curing Step>

In the curing step, as schematically shown in FIG. 1F, the curable composition (A′) is cured by being irradiated with irradiation light 107 as curing energy, thereby forming a cured film. In the curing step, for example, the curable composition (A′) is irradiated with the irradiation light 107 through the master mold 106. More specifically, the curable composition (A′) filled in the fine pattern of the master mold 106 is irradiated with the irradiation light 107 through the master mold 106. Consequently, the curable composition (A′) filled in the fine pattern of the master mold 106 is cured and forms a cured film 108 having the pattern.

The irradiation light 107 is selected in accordance with the sensitivity wavelength of the curable composition (A). More specifically, the irradiation light 107 is properly selected from ultraviolet light, X-ray, and an electron beam each having a wavelength of 150 nm or more and 400 nm or less. Note that the irradiation light 107 is particularly preferably ultraviolet light. This is so because many compounds commercially available as curing assistants have sensitivity to ultraviolet light. Examples of a light source that emits ultraviolet light are a high-pressure mercury lamp, an ultrahigh-pressure mercury lamp, a low-pressure mercury lamp, a Deep-UV lamp, a carbon arc lamp, a metal halide lamp, a xenon lamp, a KrF excimer laser, an ArF excimer laser, and an F₂ laser.

Note that the ultrahigh-pressure mercury lamp is particularly favorable as the light source for emitting ultraviolet light. It is possible to use one light source or a plurality of light sources. Light can be emitted to the entire region of the curable composition (A) filled in the fine pattern of the master mold, or to only a partial region thereof (by limiting the region). It is also possible to intermittently emit light to the entire region of the mold base material a plurality of times, or to continuously emit light to the entire region of the mold base material.

Furthermore, a first region of the mold base material can be irradiated with light in a first irradiation process, and a second region different from the first region of the mold base material can be irradiated with light in the second irradiation process.

### <Mold Release Step>

In the mold release step, as schematically shown in FIG. 1G, the master mold 106 is released from the cured film 108. By releasing the cured film 108 having a pattern and the master mold 106 from each other, the cured film 108 having a pattern formed by inverting the fine pattern of the master mold 106 is obtained in an independent state on the mold base material. Here, a cured film remains in the concave portions of the cured film 108 having the pattern corresponding to the pattern of the master mold 106. This film is called a residual film.

A method of releasing the master mold 106 from the cured film 108 having the pattern can be any method provided that the method does not physically break a part of the cured film 108 having the pattern during the release, and various conditions and the like are not particularly limited. For example, it is possible to fix the mold base material 101 and move the master mold 106 away from the mold base material 101. It is also possible to fix the master mold 106 and move the mold base material 101 away from the master mold 106.

Furthermore, the master mold 106 can be released from the cured film 108 having the pattern by moving both the master mold 106 and the mold base material 101 in exactly opposite directions.

### <Repetition>

A series of steps (a fabrication process) having the above-described steps from the arranging step to the mold release step in this order make it possible to obtain a cured film having a desired concave-convex pattern shape (a pattern shape conforming to the concave-convex shape of the master mold 106) in a desired position.

In the first pattern forming method, a repetitive unit (shot) from the arranging step to the mold release step can be performed repetitively a plurality of times on the same mold base material, and the cured film 108 having a plurality of desired patterns at desired positions of the mold base material can be obtained.

### [Second Pattern Forming Method]

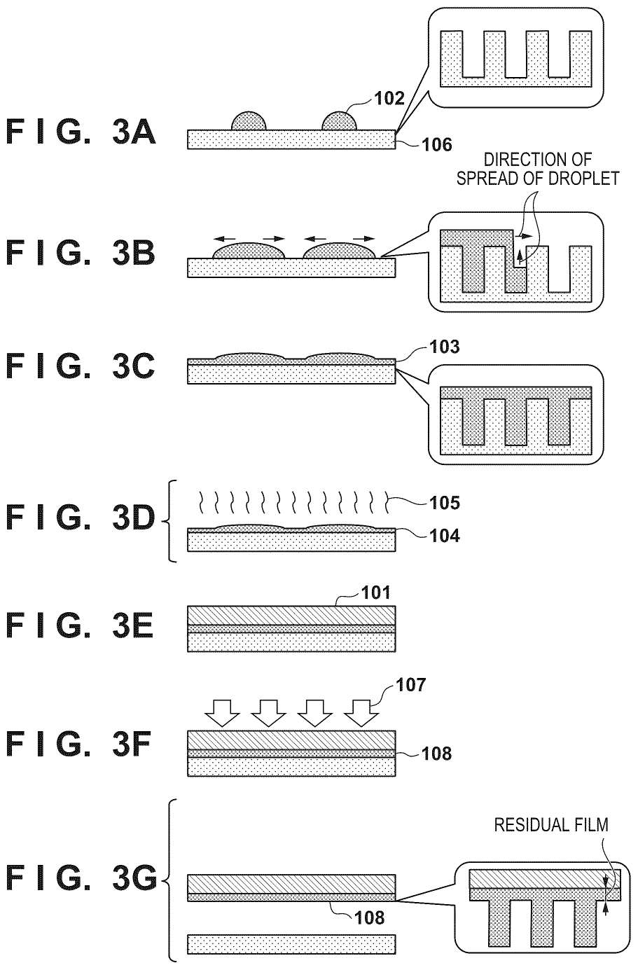

A second pattern forming method according to the present invention will be described with reference to FIGS. 3A to 3G. In the second pattern forming method, a member to which the droplets of the curable composition (A) are discretely dropped is a master mold.

An example in which film forming method according to the present invention is applied to the second pattern forming method will be described below. The second pattern forming method includes, for example, a preparation step, an arranging step, a waiting step, a contact step, a curing step, and a mold release step. The arranging step is executed after the preparation step, the waiting step is executed after the arranging step, the contact step is executed after the waiting step, the curing step is executed after the contact step, and the mold release step is executed after the curing step.

### <Arranging Step>

In the arranging step, as schematically shown in FIG. 3A, the droplets 102 of the curable composition (A) are discretely arranged on the master mold 106.

As an arranging method of arranging the droplets 102 of the curable composition (A) on the master mold, an inkjet method is particularly preferable. The droplets 102 of the curable composition (A) are densely arranged on a region where concave portions that form the pattern of the master mold 106 densely exist, and coarsely arranged on a region where concave portions that form the pattern of the master mold 106 coarsely exist. Hence, the film (residual film) of the curable composition (A) (to be described later), which is formed on the mold base material 101, is controlled to an even thickness regardless of whether the pattern of the master mold 106 is dense or coarse.

To define the volume of the curable composition (A) to be arranged on the master mold, an index called an average liquid film thickness is defined. As described above, the average liquid film thickness is a value obtained by dividing the volume of the curable composition (A) (except for the solvent (c)) arranged in the arranging step by the area of the film formation region of the master mold. The volume of the cured product or cured film of the curable composition (A) (except for the solvent (c)) is the sum of the volumes of the droplets of the curable composition (A) after volatilization of the solvent (c). According to this definition, even if the surface of the mold base material has a concave-convex pattern, the average liquid film thickness can be defined regardless of the concave-convex state.

### <Waiting Step>

In the present invention, the waiting step is provided after the arranging step and before the contact step (between the arranging step and the contact step). Here, as described above, a value obtained by dividing the total volume of the droplets of the curable composition (A) dropped in one pattern formation by the total area of the region (film formation region) where a pattern is formed by one pattern formation is defined as an average film thickness. In the waiting step, the droplets 102 of the curable composition (A) spread on the master mold 106, as schematically shown in FIG. 3B. The whole pattern formation region of the master mold 106 is covered with the curable composition (A). If the average film thickness is 130 nm or more, as schematically shown in FIG. 3C, the droplets of the curable composition (A) combine with each other on the master mold, and the practically continuous liquid film 103 is formed. If the average film thickness is 150 nm or more, the surface of the liquid film 103 is flat.

A flow behavior of the droplets of the curable composition (A) arranged on the master mold during the waiting step is the same as the flow behavior of the droplets of the curable composition (A) arranged on the mold base material during the waiting step described with reference to FIGS. 2A to 2D. More specifically, “mold base material” need only be replaced with “master mold”, and a detailed description thereof will be omitted here.

Furthermore, in the waiting step, as schematically shown in FIG. 3D, the solvent 105 (solvent (c)) contained in the liquid film 103 is volatilized. Assuming that the total weight of the components except for the solvent (c) is 100 vol %, the residual amount of the solvent (c) in a liquid film 104 after the waiting step (for example, at the contact step) is preferably 10 vol % or less. If the residual amount of the solvent (c) is larger than 10 vol %, the mechanical properties of the cured film may deteriorate.

In the waiting step, it is possible to perform a baking step of heating the master mold 106 and the curable composition (A), or ventilate the atmospheric gas around the master mold 106, for the purpose of accelerating the volatilization of the solvent (c). The heating is performed at, for example, 30° C. or more and 200° C. or less, preferably 80° C. or more and 150° C. or less, and particularly preferably 90° C. or more and 110° C. or less. The heating time can be 10 sec or more and 600 sec or less. The baking step can be performed by using a known heater such as a hotplate or an oven.

The waiting step is, for example, 0.1 to 600 sec, and preferably 10 to 300 sec. If the waiting step is shorter than 0.1 sec, the combination of the droplets of the curable composition (A) becomes insufficient, so no practically continuous liquid film is formed. If the waiting step exceeds 600 sec, the productivity decreases. To suppress the decrease in productivity, therefore, it is also possible to sequentially move the master mold completely processed in the arranging step to the waiting step, perform the waiting step in parallel to a plurality of master molds, and sequentially move the master molds completely processed in the waiting step to the contact step.

In the waiting step, when the solvent (c) volatilizes, the practically continuous liquid film 104 of a composition made of the components (as), (af), (a), (b), and (d), that is, the curable composition (A′) remains. The average film thickness of the practically continuous liquid film 104 of the curable composition (A) from which the solvent (c) is volatilized (removed), that is, the curable composition (A′) is smaller than that of the liquid film 103 by an amount of volatilization of the solvent (c). A state in which the pattern formation region of the master mold 106 is wholly covered with the practically continuous liquid film 104 of the curable composition (A′) is maintained.

### <Contact Step>

In the contact step, as schematically shown in FIG. 3E, the practically continuous liquid film 104 of the curable composition (A) from which the solvent (c) is removed, that is, the curable composition (A′) is brought into contact with the mold base material 101. The contact step includes a step of a changing a state in which the curable composition (A′) and the mold base material 101 are not in contact with each other to a state in which they are in contact with each other, and a step of maintaining the state in which they are in contact with each other.

In the waiting step, since the solvent (c) is removed from the curable composition (A), and the practically continuous liquid film 104 of the curable composition (A′) is formed, the volume of a gas entrapped between the master mold 106 and the mold base material 101 is small. Hence, the spread of the curable composition (A′) in the contact step is quickly completed.

If the curing step includes a photoirradiation step, a base material made of a light-transmitting material is preferably used as the mold base material 101. Favorable examples of the type of the material forming the mold base material 101 are glass, quartz, PMMA, a photo-transparent resin such as a polycarbonate resin, a transparent metal deposition film, a soft film such as polydimethylsiloxane, a photo-cured film, and a metal film. Note that when using the photo-transparent resin as the material forming the mold base material 101, a resin that does not dissolve in components contained in a curable composition is selected. Quartz is suitable as the material forming the mold base material 101 because the thermal expansion coefficient is small and pattern distortion is small.

In the contact step, the pressure to be applied to the curable composition (A) when bringing the mold base material 101 into contact with the curable composition (A) is not particularly limited, and is, for example, 0 MPa or more and 100 MPa or less. Note that when bringing the mold base material 101 into contact with the curable composition (A), the pressure to be applied to the curable composition (A) is preferably 0 MPa or more and 50 MPa or less. Also, when bringing the mold base material 101 into contact with the curable composition (A), the pressure to be applied to the curable composition (A) is more preferably 0 MPa or more and 30 MPa or less, and further preferably 0 MPa or more and 20 MPa or less.

### <Curing Step>

In the curing step, as schematically shown in FIG. 3F, the curable composition (A′) is cured by being irradiated with irradiation light 107 as curing energy, thereby forming a cured film. In the curing step, for example, the curable composition (A′) is irradiated with the irradiation light 107 through the mold base material 101. More specifically, the curable composition (A′) filled in the fine pattern of the master mold 106 is irradiated with the irradiation light 107 through the mold base material 101. Consequently, the curable composition (A′) filled in the fine pattern of the master mold 106 is cured and forms a cured film 108 having the pattern.

In the irradiation step, light can be emitted to the entire region of the curable composition (A) filled in the fine pattern of the master mold, or to only a partial region thereof (by limiting the region). It is also possible to intermittently emit light to the entire region of the master mold a plurality of times, or to continuously emit light to the entire region of the master mold. Furthermore, a first region of the master mold can be irradiated with light in a first irradiation process, and a second region different from the first region of the master mold can be irradiated with light in the second irradiation process.

### <Mold Release Step>

In the mold release step, as schematically shown in FIG. 3G, the master mold 106 is released from the cured film 108. By releasing the cured film 108 having a pattern and the master mold 106 from each other, the cured film 108 having a pattern formed by inverting the fine pattern of the master mold 106 is obtained in an independent state on the mold base material. Here, a cured film, that is, a residual film remains in the concave portions of the cured film 108 having the pattern corresponding to the pattern of the master mold 106.

A method of releasing the master mold 106 from the cured film 108 having the pattern can be any method provided that the method does not physically break a part of the cured film 108 having the pattern during the release, and various conditions and the like are not particularly limited. For example, it is possible to fix the mold base material 101 and move the master mold 106 away from the mold base material 101. It is also possible to fix the master mold 106 and move the mold base material 101 away from the master mold 106. Furthermore, the master mold 106 can be released from the cured film 108 having the pattern by moving both the master mold 106 and the mold base material 101 in exactly opposite directions.

If the glass transition temperature of the curable composition is much higher than the temperature at the time of mold release, the cured product at the time of mold release exhibits a firm glass state, that is, a high mechanical strength, and therefore, collapse or break of the pattern caused by impact of mold release hardly occurs. Hence, when executing the mold release step at room temperature, the glass transition temperature of the cured product is preferably 70° C. or more, more preferably 100° C. or more, and particularly preferably 150° C. or more.

As a method of measuring the glass transition temperature of the cured product, a method of performing measurement using differential scanning calorimetry (DSC) or a dynamic viscoelasticity measuring apparatus can be applied. For example, a case where the glass transition temperature is measured using DSC will be examined. In this case, a line obtained by extending the baseline (a DSC curve portion in a temperature region where neither transition nor reaction occur in a test piece) of a DSC curve on the low temperature side to the high temperature side, and a tangent drawn at a point where the gradient of the curve of a stepwise change portion of glass transition is maximum are acquired.

An extrapolated glass transition start temperature (Tig) is obtained from the intersection of the line and the tangent, and this can be obtained as the glass transition temperature. STA-6000 (manufactured by Perkin Eimer) or the like can be used as the main apparatus. On the other hand, when measuring the glass transition temperature using a dynamic viscoelasticity measuring apparatus, a temperature at which the loss sine (tanδ) of the cured product is maximum is defined as the glass transition temperature. MCR301 (manufactured by Anton Paar) or the like can be used as the main apparatus for measuring the dynamic viscoelasticity.

### EXAMPLES

More practical examples will be explained in order to supplement the above-described embodiments.

### <Conditions for Obtaining Practically Continuous Liquid Film>

Droplets of a curable composition (A) having a surface tension of 24 mN/m, a viscosity of 30 mPa·s, and a volume of 1 pL were dropped (arranged) in a square array at a predetermined interval on a flat substrate (mold base material). A behavior that each droplet of the curable composition (A) spread on the substrate was calculated by numerical calculation based on Navier-Stokes equations that had undergone a thin-film approximation method (lubrication theory) with a free surface. The thickness of the liquid film at the center of a drop position (the thickest portion of the liquid film on the substrate) and the thickness of the liquid film at the center of a square formed by four droplets arrayed in a square (the thinnest portion of the liquid film on the substrate) after the elapse of 300 sec from the drop of the droplets of the curable composition (A) are shown in Table 1 below. Note that assume that the contact angle of a droplet of the curable composition (A) with respect to the substrate is 0°, and volatilization of a solvent (c) during 300 sec from the drop of the droplets of the curable composition (A) can be neglected.

TABLE 1

| | | | | | | Com- | Com- | Com- |
|---|---|---|---|---|---|---|---|---|
| | | | | | | par- | par- | par- |
| | Ex- | Ex- | Ex- | Ex- | Ex- | ative | ative | ative |
| | am- | am- | am- | am- | am- | Exam- | Exam- | Exam- |
| | ple | ple | ple | ple | ple | ple | ple | ple |
| | 1 | 2 | 3 | 4 | 5 | 1 | 2 | 3 |
| droplet | 63 | 70 | 81 | 84 | 88 | 91 | 95 | 100 |
| pitch | | | | | | | | |
| (μm) | | | | | | | | |
| average | 252 | 204 | 153 | 142 | 130 | 120 | 111 | 100 |
| thickness | | | | | | | | |
| (nm) | | | | | | | | |
| thickness | 252 | 204 | 153 | 145 | 160 | 164 | 170 | 180 |
| of | | | | | | | | |
| thickest | | | | | | | | |
| portion | | | | | | | | |
| (nm) | | | | | | | | |
| thickness | 252 | 204 | 153 | 138 | 84 | 0 | 0 | 0 |
| of | | | | | | | | |
| thinnest | | | | | | | | |
| portion | | | | | | | | |
| (nm) | | | | | | | | |

Referring to Table, 1, in Examples 1 to 5 in which the average film thickness was 130 nm or more, it was found that the whole region of the substrate was covered with the curable composition (A). Furthermore, in Examples 1 to 3 in which the average film thickness was 150 nm or more, it was found that a flat liquid film in which the difference between the thickness of the thickest portion and the thickness of the thinnest portion was substantially 0 nm was formed.

### <Examination of Controllability of Average Film Thickness>

Both the droplet volume and the square array pitch of the curable composition (A) can be changed, but the liquid film thickness before volatilization of the solvent (c) is 130 nm, as described above, even in the region with the minimum liquid film thickness. The thickness of the liquid film remaining after volatilization of the solvent (c) from a state in which a practically continuous liquid film is formed is calculated. Assuming that the minimum value of the square array pitch of droplets of the curable composition (A) dropped onto the substrate was 35 μm, the maximum value of the thickness before the mold (master mold) was brought into contact was calculated. The minimum value of the thickness of the liquid film before volatilization of the solvent (c) with which a practically continuous liquid film was formed was calculated as 130 nm, as described above. For this reason, the minimum value of the thickness of the liquid film before the mold is brought into contact can be calculated by main component concentration (vol %)×130 nm. Here, the main component concentration (vol %) is a value obtained by subtracting vol % of the solvent (c) from 100 vol %. A case where the volume of the droplet of the curable composition (A) is 1.0 pL is shown in Table 2 below, and a case where the volume of the droplet of the curable composition (A) is 3.0 pL is shown in Table 3 below.

TABLE 2
Average residual film thickness in a case where the volume
of the droplet of the curable composition (A) is 1.0 pL

| | Exam- | Exam- | Exam- | Exam- | Exam- | Exam- |
|---|---|---|---|---|---|---|
| | ple 6 | ple 7 | ple 8 | ple 9 | ple 10 | ple 11 |
| main | 5 | 10 | 15 | 20 | 25 | 30 |
| component | | | | | | |
| concentration | | | | | | |
| (vol %) | | | | | | |
| maximum film | 41 | 82 | 122 | 163 | 205 | 245 |
| thickness (nm) | | | | | | |
| minimum film | 7 | 14 | 20 | 26 | 33 | 39 |
| thickness (nm) | | | | | | |

TABLE 3
Average residual film thickness in a case where the volume of
the droplet of the curable composition (A) is 3.0 pL

| | Exam- | Exam- | Exam- | Exam- | Exam- | Exam- |
|---|---|---|---|---|---|---|
| | ple 6 | ple 7 | ple 8 | ple 9 | ple 10 | ple 11 |
| main | 5 | 10 | 15 | 20 | 25 | 30 |
| component | | | | | | |
| concentration | | | | | | |
| (vol %) | | | | | | |
| maximum film | 123 | 245 | 366 | 490 | 615 | 735 |
| thickness (nm) | | | | | | |
| minimum film | 7 | 13 | 20 | 26 | 33 | 39 |
| thickness (nm) | | | | | | |

For example, the film thickness required in film formation including pattern formation (or planarization) in a photolithography step for manufacturing a semiconductor device is 30 nm or more and 200 nm or less. Referring to Tables 2 and 3, if the main component concentration is 10 vol % or more, a film (thick film) having a thickness of 200 nm or more can be formed. If the main component concentration is 20 vol % or less, a film (thin film) having a thickness of 30 nm or less can be formed.

### <Evaluation of Discharge Property and Filling Property of Inkjet>

The curable composition (A) was mixed such that the total weight of components (as), (a), (b), and (c) was 100 wt % in accordance with Table 4 below.

Also, the curable composition (A) was mixed without using the components (a) and (c). Table 5 below shows a result of measuring the viscosities of the curable compositions (A) at 23° C. Note that abbreviations in Table 4 are as follows. “component (as)”
TM-0701T: 3-methacryloxypropyl tris(trimethylsiloxy)silane (manufactured by JNC)
AC-SQ TA-100: silsesquioxane derivatives with acrylate groups (manufactured by
TOAGOSEI) “component (af)”
Viscoat 8F: 1H,1H,5H-octafluoropentyl acrylate (manufactured by OSAKA ORGANIC CHEMICAL INDUSTRY)
“component (a)”
IBXA: isobornyl acrylate (manufactured by OSAKA ORGANIC CHEMICAL INDUSTRY)
DCP-A: dimethylol-tricyclodecanediacrylate (KYOEISHA CHEMICAL)
“component (b)”
Omnirad 819: phenylbis(2,4,6-trimethylbenzoyl)phosphine oxide (manufactured by IGM Resin)
“component (c)”
tBuG-Bu: ethylene glycol di-tert-butyl ether (manufactured by NIPPON NYUKAZAI) (boiling point: 165° C.)
MDG-tBu: diethylene glycol methyl tert-butyl ether (manufactured by NIPPON NYUKAZAI) (boiling point: 185° C.)
MFDG-tBu: 3,10,12,12-tetramethyl-2,5,8,11-tetraoxatridecane (manufactured by NIPPON NYUKAZAI) (boiling point: 201° C.)
EOFP: 5H-ethyl octafluorovaleric acid (manufactured by Tokyo Chemical Industry) (boiling point: 142° C.)
PFEI: 2-perfluorohexylethyl iodide (manufactured by DAIKIN) (boiling point: 180° C.)
PGMEA: propylene glycol monomethyl ether acetate (manufactured by KANTO CHEMICAL)(boiling point: 146° C.)
2-trifluoromethyl-3-ethoxydodecafluorohexane (manufactured by FUJIFILM Wako Pure Chemical) (boiling point: 130° C.)

TABLE 4

| | Polymerizable compound (a) | | | | | | | |
|---|---|---|---|---|---|---|---|---|
| | Polymerizable | | Polymerizable | | | | | |
| | monomer | | monomer | | Polymerization | | Solvent | |
| | (monofunction) | | (polyfunction) | | initiator (b) | | (c) | |
| | Name | Amount | Name | Amount | Type | Amount | Type | Amount |
| Ex- | isobornyl | 0 | Acryloyl | 40 | Omni | 1.0 | tBuG- | 59.0 |
| am- | acrylate | | group- | | rad819 | | tBu | |
| ple | | | modified | | | | | |
| 12 | | | silsesquioxane | | | | | |
| | | | derivatives | | | | | |
| Ex- | isobornyl | 2 | Acryloyl | 38 | Omni | 1.0 | tBuG- | 59.0 |
| am- | acrylate | | group- | | rad819 | | tBu | |
| ple | | | modified | | | | | |
| 13 | | | silsesquioxane | | | | | |
| | | | derivatives | | | | | |
| Ex- | isobornyl | 10 | Acryloyl | 30 | Omni | 1.0 | tBuG- | 59.0 |
| am- | acrylate | | group- | | rad819 | | tBu | |
| ple | | | modified | | | | | |
| 14 | | | silsesquioxane | | | | | |
| | | | derivatives | | | | | |
| Ex- | isobornyl | 20 | Acryloyl | 20 | Omni | 1.0 | tBuG- | 59.0 |
| am- | acrylate | | group- | | rad819 | | tBu | |
| ple | | | modified | | | | | |
| 15 | | | silsesquioxane | | | | | |
| | | | derivatives | | | | | |
| Ex- | isobornyl | 25 | Acryloyl | 15 | Omni | 1.0 | tBuG- | 59.0 |
| am- | acrylate | | group- | | rad819 | | tBu | |
| ple | | | modified | | | | | |
| 16 | | | silsesquioxane | | | | | |
| | | | derivatives | | | | | |
| Ex- | isobornyl | 20 | Acryloyl | 20 | Omni | 1.0 | MDG-tBu | 59.0 |
| am- | acrylate | | group- | | rad819 | | | |
| ple | | | modified | | | | | |
| 17 | | | silsesquioxane | | | | | |
| | | | derivatives | | | | | |
| Ex- | isobornyl | 20 | Acryloyl | 20 | Omni | 1.0 | MFDG- | 59.0 |
| am- | acrylate | | group- | | rad819 | | tBu | |
| ple | | | modified | | | | | |
| 18 | | | silsesquioxane | | | | | |
| | | | derivatives | | | | | |
| Ex- | isobornyl | 20 | Acryloyl | 20 | Omni | 1.0 | EOFP | 59.0 |
| am- | acrylate | | group- | | rad819 | | | |
| ple | | | modified | | | | | |
| 19 | | | silsesquioxane | | | | | |
| | | | derivatives | | | | | |
| Ex- | isobornyl | 20 | Acryloyl | 20 | Omni | 1.0 | PFHEI | 59.0 |
| am- | acrylate | | group- | | rad819 | | | |
| ple | | | modified | | | | | |
| 20 | | | silsesquioxane | | | | | |
| | | | derivatives | | | | | |
| Ex- | 3- | 95 | dimethylol- | 0 | Omni | 1.0 | tBuG- | 4.0 |
| am- | methacryloxypropyl | | tricyclodecanediacrylate | | rad819 | | tBu | |
| ple | tris(trimethylsiloxy)silane | | | | | | | |
| 21 | | | | | | | | |
| Ex- | 3- | 90 | dimethylol- | 5 | Omni | 1.0 | tBuG- | 4.0 |
| am- | methacryloxypropyl | | tricyclodecanediacrylate | | rad819 | | tBu | |
| ple | tris(trimethylsiloxy)silane | | | | | | | |
| 22 | | | | | | | | |
| Ex- | 3- | 60 | dimethylol- | 20 | Omni | 1.0 | tBuG- | 19.0 |
| am- | methacryloxypropyl | | tricyclodecanediacrylate | | rad819 | | tBu | |
| ple | tris(trimethylsiloxy)silane | | | | | | | |
| 23 | | | | | | | | |
| Ex- | 3- | 50 | dimethylol- | 20 | Omni | 1.0 | EOFP | 29.0 |
| am- | methacryloxypropyl | | tricyclodecanediacrylate | | rad819 | | | |
| ple | tris(trimethylsiloxy)silane | | | | | | | |
| 24 | | | | | | | | |
| Ex- | 3- | 45 | dimethylol- | 25 | Omni | 1.0 | PFHEI | 29.0 |
| am- | methacryloxypropyl | | tricyclodecanediacrylate | | rad819 | | | |
| ple | tris(trimethylsiloxy)silane | | | | | | | |
| 25 | | | | | | | | |
| Ex- | 1H,1H,5H- | 30 | dimethylol- | 24 | Omni | 1.0 | tBuG- | 45.0 |
| am- | octafluoropentyl | | tricyclodecanediacrylate | | rad819 | | tBu | |
| ple | acrylate | | | | | | | |
| 26 | | | | | | | | |
| Ex- | 1H,1H,5H- | 30 | dimethylol- | 20 | Omni | 1.0 | tBuG- | 49.0 |
| am- | octafluoropentyl | | tricyclodecanediacrylate | | rad819 | | tBu | |
| ple | acrylate | | | | | | | |
| 27 | | | | | | | | |
| Ex- | 1H,1H,5H- | 30 | dimethylol- | 15 | Omni | 1.0 | tBuG- | 54.0 |
| am- | octafluoropentyl | | tricyclodecanediacrylate | | rad819 | | tBu | |
| ple | acrylate | | | | | | | |
| 28 | | | | | | | | |
| Ex- | 1H,1H,5H- | 30 | dimethylol- | 10 | Omni | 1.0 | tBuG- | 58.0 |
| am- | octafluoropentyl | | tricyclodecanediacrylate | | rad819 | | tBu | |
| ple | acrylate | | | | | | | |
| 29 | | | | | | | | |
| Com- | isobornyl | 10 | Acryloyl | 30 | Omni | 1.0 | PGMEA | 59.0 |
| para- | acrylate | | group- | | rad819 | | | |
| rat- | | | modified | | | | | |
| ive | | | silsesquioxane | | | | | |
| ex- | | | derivatives | | | | | |
| am- | | | | | | | | |
| ple | | | | | | | | |
| 4 | | | | | | | | |
| Com- | isobornyl | 0 | Acryloyl | 40 | Omni | 1.0 | 2- | 59.0 |
| para- | acrylate | | group- | | rad819 | | Trifluoromethyl- | |
| rative | | | modified | | | | 3- | |
| ex- | | | silsesquioxane | | | | ethoxydodeca- | |
| am- | | | derivatives | | | | fluorohexane | |
| ple | | | | | | | | |
| 5 | | | | | | | | |
| Com- | isobornyl | 63 | Acryloyl | 32 | Omni | 1.0 | PGMEA | 4.0 |
| para- | acrylate | | group- | | rad819 | | | |
| rative | | | modified | | | | | |
| ex- | | | silsesquioxane | | | | | |
| am- | | | derivatives | | | | | |
| ple | | | | | | | | |
| 6 | | | | | | | | |

TABLE 5

| | Physical property value | | | | |
|---|---|---|---|---|---|
| | Viscosity | Boiling | | | |
| | of curable | point | | | |
| | composition | of the | | | |
| | (a) | solvent (c) | γ1 | γ2 | γ1 − γ2 |
| | (mPa · s) | (° C.) | (mN/m) | (mN/m) | (mN/m) |
| Example 12 | 37.5 | 165 | 22.0 | 21.8 | 0.2 |
| Example 13 | 32.9 | 165 | 23.3 | 21.8 | 1.5 |
| Example 14 | 19.4 | 165 | 26.8 | 21.8 | 5.0 |
| Example 15 | 10.1 | 165 | 29.2 | 21.8 | 7.4 |
| Example 16 | 7.3 | 165 | 30.0 | 21.8 | 8.2 |
| Example 17 | 10.6 | 185 | 29.2 | 23.2 | 6.0 |
| Example 18 | 12.4 | 201 | 29.2 | 23.8 | 5.4 |
| Example 19 | 10.1 | 142 | 29.2 | 17.9 | 11.3 |
| Example 20 | 10.1 | 180 | 29.2 | 18.4 | 10.8 |
| Example 21 | 4.3 | 165 | 21.9 | 21.8 | 0.1 |
| Example 22 | 5.1 | 165 | 23.1 | 21.8 | 1.3 |
| Example 23 | 6.9 | 165 | 27.2 | 21.8 | 5.4 |
| Example 24 | 6.0 | 142 | 27.9 | 17.9 | 10.0 |
| Example 25 | 7.1 | 180 | 29.2 | 18.4 | 10.8 |
| Example 26 | 5.0 | 165 | 29.9 | 21.8 | 8.1 |
| Example 27 | 4.1 | 165 | 29.3 | 21.8 | 7.5 |
| Example 28 | 3.3 | 165 | 28.3 | 21.8 | 6.5 |
| Example 29 | 2.6 | 165 | 27.0 | 21.8 | 5.2 |
| Comparative | 18.4 | 146 | 26.8 | 27.6 | −0.8 |
| example 4 | | | | | |
| Comparative | 37.5 | 130 | 22.0 | 14.5 | 7.5 |
| example 5 | | | | | |
| Comparative | 67.6 | 146 | 30.2 | 27.6 | 2.6 |
| example 6 | | | | | |

### <Evaluation of Discharge Speed of Inkjet>

To evaluate the discharge speed of inkjet, a commercially available industrial material printer DMP-2850 (manufactured by FUJIFILM) was used. Each of curable compositions of Examples 12 to 29 and Comparative Examples 4 to 6 shown in Table 4 was filled in a cartridge (1 pL). A droplet discharge state was observed by an internal discharge observation camera, and the discharge speed of inkjet was evaluated based on the following evaluation criteria.

### (Evaluation Criteria)

AAA: At a discharge speed (flying speed) of 6 m/sec or more, no deviation (distortion) of the landing position was observed at all.
AA: At a discharge speed of 6 m/sec or more, very slight deviation of the landing position without practical influence was observed.
A: At a discharge speed of 4 m/sec or more, very slight deviation of the landing position without practical influence was observed.
B: Discharge was not performed.

### <Evaluation of Intermittent Discharge Property of Inkjet>

To evaluate the intermittent discharge property of inkjet, a commercially available industrial material printer DMP-2850 (manufactured by FUJIFILM) was used. Each of curable compositions of Examples 12 to 29 and Comparative Examples 4 to 6 shown in Table 4 was filled in a cartridge (1 pL). Droplets were discharged from all (12) nozzles for 1 sec at a frequency of 40 kHz. After a predetermined rest time, one droplet was discharged from each nozzle, the state thereof was observed by an internal discharge observation camera, and the intermittent discharge property of inkjet was evaluated based on the following evaluation criteria.

### (Evaluation Criteria)

AAA: Even after a rest time of 10 sec, more than half of nozzles could discharge droplets.
AA: Even after a rest time of 5 sec, more than half of nozzles could discharge droplets.
A: Even after a rest time of 3 sec, more than half of nozzles could discharge droplets.
B: After a rest time of 3 sec, more than half of nozzles could not discharge droplets.

### <Evaluation of Filling Property>

Under a condition that the thickness of a liquid film before volatilization of the solvent (c) was 130 nm, each of the curable compositions (A) of Examples 12 to 29 and Comparative Examples 4 to 6 shown in Table 4 was discretely dropped (arranged) on a silicon substrate. Time until a practically continuous liquid film was formed was measured, and the filling property was evaluated based on the following evaluation criteria.

### (Evaluation Criteria)

AAA: A practically continuous liquid film was formed in a time less than 100 sec.
AA: A practically continuous liquid film was formed in a time of 100 sec or more and less than 200 sec.
A: A practically continuous liquid film was formed in a time of 200 sec or more and less than 300 sec.
B: A practically continuous liquid film was not formed even after the elapse of time of 300 sec.

Table 6 shows the evaluation results.

TABLE 6

| | Evaluation result | | |
|---|---|---|---|
| | | Intermittent | |
| | | discharge | Filling |
| | Discharge speed | property | property |
| Example 12 | A | AAA | A |
| Example 13 | A | AAA | AA |
| Example 14 | AA | AAA | AAA |
| Example 15 | AAA | AAA | AAA |
| Example 16 | AAA | AAA | AAA |
| Example 17 | AAA | AAA | AAA |
| Example 18 | AAA | AA | AAA |
| Example 19 | AAA | A | AAA |
| Example 20 | AAA | AAA | AAA |
| Example 21 | AAA | AAA | A |
| Example 22 | AAA | AAA | AA |
| Example 23 | AAA | AAA | AAA |
| Example 24 | AAA | A | AAA |
| Example 25 | AAA | AAA | AAA |
| Example 26 | AAA | AAA | AAA |
| Example 27 | AAA | AAA | AAA |
| Example 28 | AAA | AAA | AAA |
| Example 29 | A | AAA | AAA |
| Comparative example 4 | AA | AA | B |
| Comparative example 5 | A | B | AAA |
| Comparative example 6 | B | AA | AAA |

It can be found that if the viscosity of the curable composition at 23° C. is 1.3 mPa·s or more and 60 mPa·s or less, the discharge of inkjet is excellent, and the viscosity is preferably 5 mPa·s or more and 30 mPa·s or less, and more preferably 5 mPa·s or more and 15 mPa·s or less.

It can be found that if the boiling point of the solvent contained in the curable composition is 135° C. or more, the intermittent discharge property of inkjet is excellent, and the boiling point is preferably 145° C. or more and 250° C. or less, and more preferably 150° C. or more and 200° C. or less.

It can be found that defining the surface tension of nonvolatile components except for the solvent at 23° C. as γ1 [mN/m] and the surface tension of the solvent at 23° C. as γ2 [mN/m], if γ1 is 30 or less, γ2 is 24 or less, and γ1 is larger than γ2, the filling property is excellent. If can also be found that γ1-γ2>0.1 is preferable, and γ1-γ2>1 is more preferable.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2023-146501 filed on Sep. 8, 2023, which is hereby incorporated by reference herein in its entirety.

What is claimed is:

1. A curable composition containing a polymerizable compound (a), a photopolymerization initiator (b), and a solvent (c), wherein
the curable composition has a viscosity of not less than 1.3 mPa·s and not more than 60 mPa·s at 23° C. and at 1 atm,
a content of the solvent (c) with respect to whole of the curable composition is not less than 5 vol % and not more than 95 vol %,
a boiling point of the solvent (c) is not less than 135° C. at 1 atm, and
defining a surface tension of a composition obtained by removing the solvent (c) from the curable composition at 1 atm as γ1 [mN/m] and the surface tension of the solvent (c) at 23° C. and at 1 atm as γ2 [mN/m], γ1 is not more than 30, γ2 is not more than 24, and γ1 is larger than γ2.

2. The curable composition according to claim 1, wherein γ1-γ2>0.1 [mN/m].

3. The curable composition according to claim 1, wherein γ1-γ2>0.1 [mN/m].

4. The curable composition according to claim 1, wherein the solvent (c) contains silicon atoms or fluorine atoms at not more than 10 at %.

5. The curable composition according to claim 1, wherein the polymerizable compound (a) includes a compound containing silicon atoms or fluorine atoms.

6. The curable composition according to claim 1, wherein the boiling point of the solvent (c) is not less than 130° C. and less than 250° C. at 1 atm.

7. The curable composition according to claim 1, wherein the solvent (c) includes polyhydric alcohol ether obtained by alkyl-etherifying all hydroxyl groups of polyhydric alcohol.

8. The curable composition according to claim 1, wherein the solvent (c) contains one of ethylene glycol ditertiary butyl ether and diethylene glycol methyl tertiary butyl ether.

9. A curable composition containing a polymerizable compound (a), a photopolymerization initiator (b), and a solvent (c), wherein
the curable composition has a viscosity of not less than 1.3 mPa·s and not more than 60 mPa·s at 23° C. and at 1 atm,
a content of the solvent (c) with respect to whole of the curable composition is not less than 5 vol % and not more than 95 vol %, and
the solvent (c) contains one of ethylene glycol ditertiary butyl ether and diethylene glycol methyl tertiary butyl ether.

10. A film forming method of forming a film of a curable composition in a space between a mold and a substrate, comprising:
discretely arranging a plurality of droplets of a curable composition defined in claim 1 on one of the substrate and the mold;
waiting until each of the plurality of droplets combines with an adjacent droplet to form a liquid film; and
bringing the mold and the liquid film into contact with each other after the waiting.

11. The method according to claim 10, wherein in the waiting, the waiting is performed until a solvent contained in the liquid film volatilizes, and a content of the solvent becomes not more than 10 vol % with respect to whole the liquid film.

12. The method according to claim 10, wherein in the waiting, the substrate is heated under conditions of not less than 30° C. and not more than 200° C. and not less than 10 sec and not more than 600 sec.

13. The method according to claim 10, wherein in the arranging, the droplets of the curable composition each having a volume of not less than 1.0 pL are arranged at a density of not less than 130 pieces/mm².

14. The method according to claim 10, wherein an average film thickness that is a value obtained by dividing a volume of the curable composition remaining after the waiting by an area of a film formation region where the film is formed is not more than 10 μm.

15. The method according to claim 10, wherein
the mold includes a master mold, and
the substrate includes a mold base material.

16. The method according to claim 15, wherein
the master mold includes a pattern, and
the method further comprises curing the film to form a cured film having a pattern corresponding to the pattern of the master mold after the bringing the mold and the liquid film into contact with each other.

17. The method according to claim 10, wherein in the arranging, the plurality of droplets are discretely arranged using an inkjet method.

18. A manufacturing method comprising manufacturing a replica mold by forming, on a mold base material, a cured film having a pattern corresponding to a pattern of a master mold using a film forming method defined in claim 16.

19. A film forming method of forming a film of a curable composition in a space between a mold and a substrate, comprising:
discretely arranging a plurality of droplets of a curable composition defined in claim 9 on one of the substrate and the mold;
waiting until each of the plurality of droplets combines with an adjacent droplet to form a liquid film; and
bringing the mold and the liquid film into contact with each other after the waiting.
